(19) United States
(12) Patent Application Publication
(10) Pub. No.: US 2026/0304799 A1
(43) Pub. Date: Oct. 1, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Hsiao-Hua HUNG, Hsinchu City (TW); Kuo-Chang CHIANG, Hsinchu City (TW); Ming-Yen CHUANG, Hsinchu City (TW)

(21) Appl. No.: 19/095,515

(22) Filed: Mar. 31, 2025

(51) Int. Cl. H10D 1/66; H01L 23/522; H01L 23/528; H10D 1/00

(52) U.S. Cl. CPC H10D 1/665; H10D 1/047; H10W 20/435; H10W 20/496

(57) ABSTRACT

Air gaps are formed in capacitor structures to reduce parasitic capacitance between closely spaced capacitors. The air gaps may be formed on lateral sides of a deep trench capacitor structure to ensure capacitor-to-capacitor isolation and reduced parasitic capacitance. Air gaps may be formed by selective film deposition and/or by selective removal of sacrificial layers. The dielectric constant of the air gaps is less than the dielectric constant of porous low-k or bulk dielectric materials that may be used in other capacitor structures. The lesser dielectric constant of the air gaps in comparison to that of the porous low-k or bulk dielectric materials reduces the capacitive coupling between adjacent capacitor structures, thus suppressing cross-talk and increasing signal integrity, leading to increased device performance and reliability.

### BACKGROUND

A capacitor structure, such as a deep trench capacitor (DTC) structure, may include a metal-insulator-metal (MIM) structure in which an insulator layer is sandwiched between two conductive electrode layers. Various types of semiconductor devices may include one or more capacitor structures, such as an image sensor device, a memory device (e.g., a dynamic random access memory (DRAM) device), a logic device, a processor, a system on chip (SoC), and/or an integrated passive device (IPD), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E are diagrams of an example semiconductor device described herein.

FIGS. 2A-2E are diagrams of an example implementation of forming a semiconductor device described herein.

FIGS. 3A-3K are diagrams of an example implementation of forming a trench capacitor structure described herein.

FIGS. 4A-4N are diagrams of an example implementation of forming a trench capacitor structure described herein.

FIGS. 5A-5K are diagrams of an example implementation of forming a trench capacitor structure described herein.

FIGS. 6A-6M are diagrams of an example implementation of forming a trench capacitor structure described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor structure may be included in an interconnect layer of a semiconductor device. The capacitor structure may extend through a plurality of dielectric layers in the interconnect layer and may be electrically coupled to one or more conductive structures in the interconnect layer.

As device size decreases, the spacing between capacitors also decreases, causing unwanted impacts on performance and reliability. For example, the reduced spacing between structures may increase parasitic capacitance in the capacitors in an interconnect layer, which may cause challenges such as resistance-capacitance (RC) delay. An increased RC time constant that results from the increased capacitance may result in longer signal propagation times. Several materials, including porous low-k or bulk dielectric materials, have been applied to capacitor structures to reduce parasitic capacitance between capacitors. However, these materials are prone to cracking, delamination, voids, and other structural issues, thereby reducing device reliability and performance. For example, some porous low-k or bulk dielectric materials exhibit low strength and low thermal stability, and may be prone to damage from etching and/or temperature fluctuations during semiconductor device fabrication. Such damage may lead to the structural defects noted above (e.g., cracking, delamination voids, etc.), resulting in current leakage and/or charge carrier tunnels.

In some implementations described herein, air gaps are formed in capacitor structures to reduce parasitic capacitance between closely spaced capacitors. The air gaps may be formed on lateral sides of a deep trench capacitor (DTC) structure to ensure capacitor-to-capacitor isolation and reduced parasitic capacitance. Air gaps may be formed by selective film deposition and/or by selective removal of sacrificial layers. The dielectric constant (or relative permittivity) of the air gaps is less than the dielectric constant of porous low-k or bulk dielectric materials that may be used in other capacitor structures. The lesser dielectric constant of the air gaps in comparison to that of the porous low-k or bulk dielectric materials reduces the capacitive coupling between adjacent capacitor structures, thus suppressing cross-talk and increasing signal integrity. Moreover, unlike porous low-k or bulk dielectric materials, air gaps are not subject to manufacturing process damage. As a result, using air gap structures in capacitor structures in place of porous low-k or bulk dielectric materials can reduce RC delay, maintain stable capacitance, improve signal integrity, ensure more robust mechanical strength, and lower current leakage, leading to increased device performance and reliability.

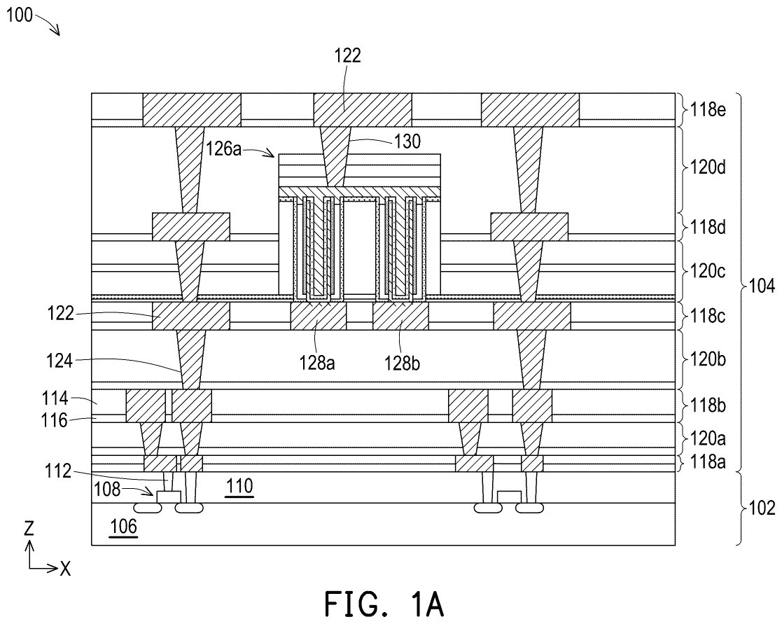

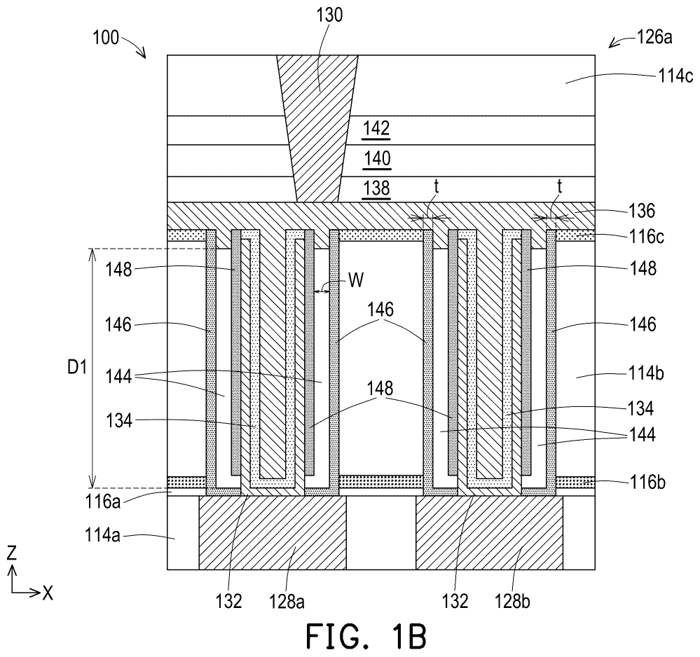

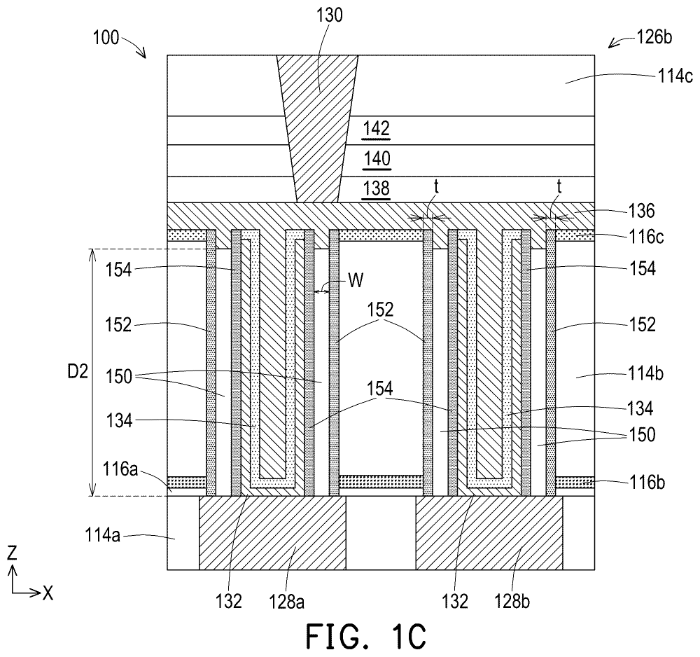

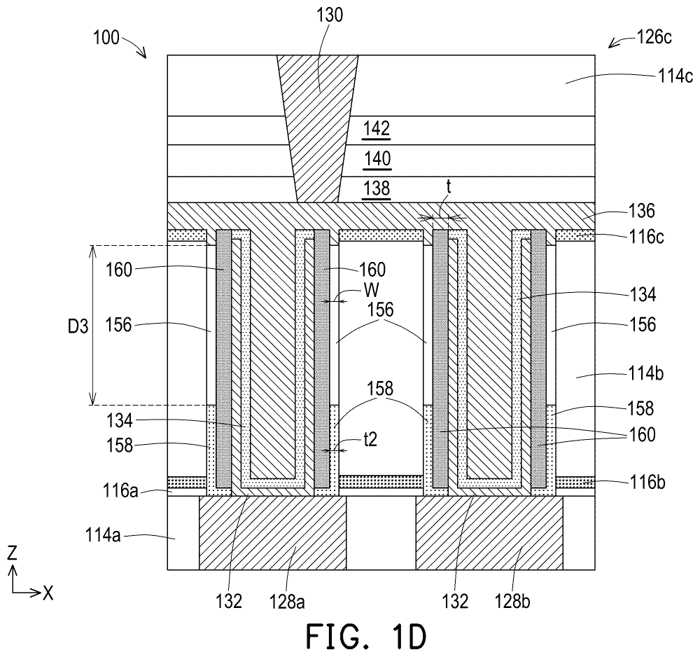

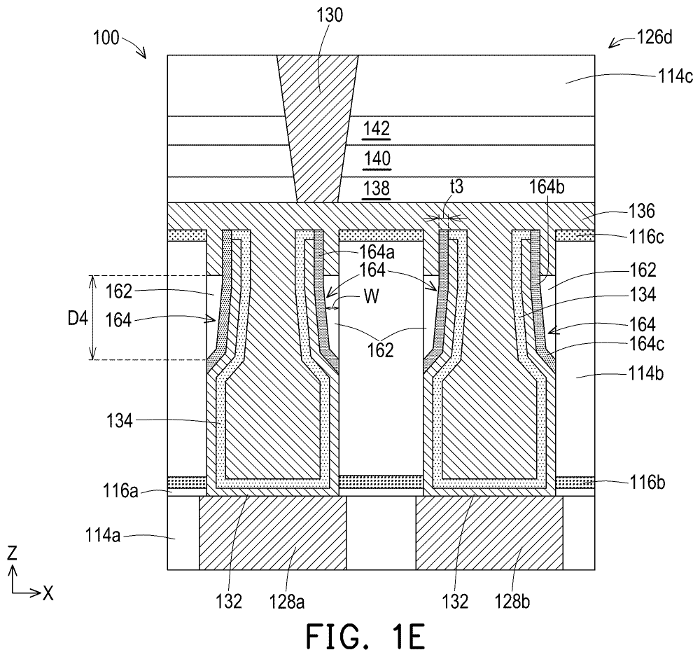

FIGS. 1A-1E illustrate cross-section views of a semiconductor device 100 including different capacitor structures. As shown in FIG. 1A, the semiconductor device 100 may include a device layer 102 and an interconnect layer 104 arranged in a z-direction in the semiconductor device 100 with respect to the device layer 102. For example, the interconnect layer 104 may be located above the device layer 102. As another example, the interconnect layer 104 may be located below the device layer 102.

The interconnect layer 104 may include conductive structures that are arranged to carry signals and/or provide power distribution throughout the semiconductor device 100. In some implementations, the semiconductor device 100 includes interconnect layers 104 above and below the device layer 102. A first interconnect layer 104 on a first side of the device layer 102 may be used for signal propagation throughout the semiconductor device 100, and a second interconnect layer 104 on an opposing second side of the device layer 102 may be used for power distribution in the semiconductor device 100.

The device layer 102 includes a substrate 106 of the semiconductor device 100. The substrate 106 may correspond to a portion of a semiconductor wafer on which the semiconductor device 100 is formed. The substrate 106 may include a silicon (Si) substrate, a substrate formed of a material including silicon, a III-V compound semiconductor material substrate such as gallium arsenide (GaAs), a silicon on insulator (SOI) substrate, or another type of substrate. The substrate 106 may extend in an x-direction and/or in a y-direction in the semiconductor device 100 such that the top and bottom surfaces of the substrate 106 are approximately orthogonal to the z-direction in the semiconductor device 100.

Integrated circuit devices 108 may be included in and/or on the substrate 106 in the device layer 102 of the semiconductor device 100. The integrated circuit devices 108 may include transistor structures (e.g., planar transistor structures, fin field effect transistor (finFET) structures, gate all around (GAA) transistor structures), pixel sensors, capacitors, resistors, inductors, photodetectors, transceivers, transmitters, receivers, optical circuits, and/or other types of front end semiconductor devices.

A transistor structure may include a plurality of source/drain regions, which may correspond to doped regions of the substrate 106, separated by a channel region in the substrate 106. In some implementations, the source/drain regions are doped with a first type of dopant (e.g., a p-type dopant such as boron (B) and/or gallium (Ga), an n-type dopant such as phosphorous (P) and/or arsenic (As)), and the channel region is doped with a second type of dopant that is different from the first type of dopant. The transistor structure may include a gate structure over and/or around the channel region. A gate dielectric layer of the transistor structure may be included between the gate structure and the channel region. The gate structure may include a polysilicon gate, a metal gate with a high dielectric constant (high-k) gate dielectric layer such as hafnium oxide (HfOₓ such as HfO₂), and/or another type of gate structure.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in the y-direction in the semiconductor device 100. Contacts 112 (e.g., source/drain contacts, gate contacts) may extend through the dielectric layer 110 and between the integrated circuit devices 108 and the interconnect layer 104. The contacts may electrically connect the integrated circuit devices 108 to the interconnect layer 104. The contacts 112 may include vias, plugs, and/or another type of elongated electrically conductive structures. The contacts 112 may include tungsten (W), cobalt (Co), ruthenium (Ru), titanium (Ti), aluminum (Al), and/or gold (Au), among other electrically conductive materials.

The interconnect layer 104 includes a plurality of dielectric layers that are arranged in a direction (e.g., the z-direction) that is approximately perpendicular to the top surface of the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include a low dielectric constant (low-k) oxide material such as silicon oxide (SiOₓ) or undoped silicate glass (USG). Additionally and/or alternatively, the ILD layers 114 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104. For example, the ILD layers 114 may each include a low-k dielectric material such as USG, and the ESLs 116 may each include a high-k dielectric material such as silicon nitride (SiₓN_{y}) or silicon carbide (SiC). Additionally and/or alternatively, two or more ESLs 116 may include different materials. For example, one or more first ESLs 116 may include silicon nitride (SiₓN_{y}), and one or more second ESLs 116 may include silicon carbide (SiC).

The interconnect layer 104 includes a plurality of conductive structures that are arranged in a plurality of layers. The conductive structures may be electrically coupled and/or physically coupled with one or more of the integrated circuit devices 108 in the device layer 102. The conductive structures provide electrical routing that enables signals and/or power to be provided to and/or from the integrated circuit devices 108.

The layers of conductive structures may include a plurality of layers 118a-118e that are vertically arranged and alternate with a plurality of layers 120a-120d in the z-direction (e.g., vertically alternate). The layers 118a-118e each include a layer of metallization structures 122, and the layers 120a-120d each include a layer of interconnect structures 124.

The layers 118a-118e of metallization structures 122 may be referred to as M-layers. For example, a layer 118a of metallization structures 122 (referred to as a metal-0 (M0) layer) may be located at the bottom of the interconnect layer 104 and may be coupled with the device layer 102. In particular, the metallization structures 122 in the M0 layer may be coupled with the contacts 112 (e.g., a contact layer referred to as “CO” layer) of the integrated circuit devices 108 in the device layer 102. A layer 118b of metallization structures 122 (referred to as a metal-1 layer (M1) layer) may be located above the layer 118a of metallization structures 122 in the interconnect layer 104, a layer 118c of metallization structures 122 (referred to as a metal-2 layer (M2) layer) may be located above the a layer 118b of metallization structures 122, and so on.

A layer 120a of interconnect structures 124 (referred to as a via-1 (V0) layer) may be included between the M0 layer and the M1 layer to interconnect the M0 layer and the M1 layer, a layer 120b of interconnect structures 124 (referred to as a via-2 (V1) layer) may be included between the M1 layer and the M2 layer to interconnect the M1 layer and the M2 layer, and so on.

The metallization structures 122 may include a combination of trenches, metallization layers, conductive traces, and/or other types of conductive structures. The interconnect structures 124 may include a combination of vias, interconnects, and/or other types of conductive structures. The metallization structures 122 and the interconnect structures 124 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 104 and the metallization structures 122, and/or between the dielectric layers of the interconnect layer 104 the interconnect structures 124. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., a topmost layer of metallization structures 122, a topmost layer of interconnect structures 124) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., a topmost layer of metallization structures 122, a topmost layer of interconnect structures 124) may be coupled to bonding structures, such as bonding pads and/or bonding vias.

As further shown in FIG. 1A, a trench capacitor structure 126a is included in the interconnect layer 104 of the semiconductor device 100. Details of the trench capacitor structure 126a are shown in FIG. 1B. As further shown in FIGS. 1C-1E, other example implementations of trench capacitor structures 126b, 126c, and 126d may be included in the interconnect layer 104 of the semiconductor device 100 in a similar arrangement to that of the trench capacitor structure 126a. The trench capacitor structures 126a-126d may extend through and/or may be included in one or more dielectric layers in the interconnect layer 104, such as one or more ILD layers 114 and/or one or more ESLs 116. In some implementations, an integrated circuit device 108 is electrically coupled to a trench capacitor structure 126a, 126b, 126c, or 126d to form a memory cell (e.g., a dynamic random access memory (DRAM) cell or another type of capacitor-based memory cell) in the semiconductor device 100. In some implementations, a trench capacitor structure 126a, 126b, 126c, or 126d is configured to provide charge decoupling for one or more integrated circuit devices 108. In some implementations, a trench capacitor structure 126a, 126b, 126c, or 126d is configured to store a charge (e.g., a photocurrent) for an integrated circuit device 108 (e.g., a pixel sensor) in the semiconductor device 100. In some implementations, a trench capacitor structure 126a, 126b, 126c, or 126d is configured to perform another function in the semiconductor device 100.

As shown in FIGS. 1A and 1B, the trench capacitor structure 126a may be electrically coupled and/or physically coupled to a first bottom contact 128a and a second bottom contact 128b at a bottom of the trench capacitor structure 126a. Similarly, as shown in FIGS. 1C-1E, the trench capacitor structures 126b-126d may be electrically coupled and/or physically coupled to the first bottom contact 128a and the second bottom contact 128b at bottoms of the trench capacitor structures 126b-126d. The first bottom contact 128a and the second bottom contact 128b may each include one or more conductive structures in the interconnect layer 104, such as one or more metallization structures 122 and/or one or more interconnect structures 124, among other examples. In some implementations, a trench capacitor structure may be electrically coupled and/or physically coupled to a top contact. For example, referring to FIGS. 1A and 1B, the trench capacitor structure 126b is coupled to a top contact 130 at a top of the trench capacitor structure 126a, which may be coupled to a metallization structure 122. Similarly, as shown in FIGS. 1C-1E, the trench capacitor structures 126b-126d may be electrically coupled and/or physically coupled to the top contact 130 at tops of the trench capacitor structures 126b-126d. The top contact 130 may include one or more conductive structures in the interconnect layer 104, such as one or more metallization structures 122 and/or one or more interconnect structures 124, among other examples.

FIG. 1B illustrates a detailed cross-section view of the trench capacitor structure 126a. In general, a capacitor structure may include an MIM structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

Increasing a lateral size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Thus, in some cases, the size of a capacitor structure may be increased in a vertical direction in a semiconductor device such that the capacitor structure extends through a plurality of layers in a semiconductor device. A DTC is a type of capacitor structure that is formed in a deep trench in a semiconductor device such that the electrode layers and insulator layer extend along, and conform to, a profile of the deep trench. This enables the area of the conductive electrode layers to be increased (which increases the capacitance) with minimal increase in the lateral size of the capacitor structure. The trench of a DTC structure is typically formed to have a high aspect ratio between the depth of the trench and the width of the trench.

As shown in FIG. 1B, the trench capacitor structure 126a includes a first trench on the first bottom contact 128a, and a second trench on the second bottom contact 128b. The first bottom contact 128a and the second bottom contact 128b may be included in an ILD layer 114a in the interconnect layer 104 of the semiconductor device 100. The first and second trenches of the trench capacitor structure 126a may extend through one or more dielectric layers in the interconnect layer 104 of the semiconductor device 100, including through an ESL 116c, an ILD layer 114b, an ESL 116b, and/or an ESL 116a, among other examples.

The ILD layer 114b may include a silicon oxide (e.g., SiO₂), an oxynitride containing dielectric material such as silicon oxynitride (SiON), a silicon nitride (e.g., SiN), a silicon carbonitride (e.g., SiCN), and/or other low-k dielectric materials. In some implementations, a thickness (e.g., z-direction dimension) of the ILD layer 114b may be included in the range of approximately 500 nanometers to approximately 2000 nanometers. However, other values and ranges for the thickness of the ILD layer 114b are within the scope of this disclosure.

The ESL 116a may include an aluminum oxynitride (e.g., AlON), an aluminum nitride (e.g., AlN), an aluminum oxide (e.g., AlO), a hafnium oxide (e.g., HfO), a zirconium oxide (e.g., ZrO), an indium zirconium oxide (e.g., InZrO), a hafnium zirconium oxide (e.g., HfZrO), a titanium oxide (e.g., TiO), a titanium aluminum oxide (e.g. TiAlO), a tantalum oxide (e.g., Ta₂O₅), and/or other materials. In some implementations, a thickness (e.g., z-direction dimension) of the ESL 116a may be included in the range of approximately 1 nanometer to approximately 15 nanometers. However, other values and ranges for the thickness of the ESL 116a are within the scope of this disclosure.

The ESLs 116b and 116c may include a silicon carbonitride (e.g., SiCN), a silicon carbide (e.g., SiC), a silicon oxycarbide (e.g., SiOC), a silicon oxycarbonitride (e.g., SiOCN), and/or other low-k dielectric materials. In some implementations, a thickness (e.g., z-direction dimension) of the ESLs 116 b and 116 c may be included in the range of approximately 5 nanometers to approximately 60 nanometers. However, other values and ranges for the thickness of the ESLs 116b and 116c are within the scope of this disclosure.

In some implementations, the first and second trenches may have a high aspect ratio, which is a ratio of a depth (or height) of the trenches to a lateral width (or critical dimension) of the trenches. Thus, the trench capacitor structure 126a may be referred to as a DTC structure. In some implementations, the aspect ratio of a trench may be approximately 10:1 or greater. In some implementations, a trench may have an aspect ratio that is included in the range of approximately 20:1 to approximately 50:1. However, other values and ranges are within the scope of the present disclosure.

As further shown in FIG. 1B, each trench of the trench capacitor structure 126a includes a bottom electrode layer 132 (e.g., first electrode layer), an insulator layer 134, and top electrode layer 136 (e.g., second electrode layer) forming a MIM structure. The trench capacitor structure 126a may include one or more capping layers above the trenches and above the MIM structure of the trench capacitor structure 126a. The one or more capping layers may include an oxide capping layer 138, an oxynitride capping layer 140, and/or a nitride capping layer 142, among other examples. The capping layers may provide electrical isolation for the MIM structure of the trench capacitor structure 126a, and/or may also function as a hard mask layer stack for forming the top contact 130. The oxide capping layer 138 may include an oxide-containing dielectric material such as silicon oxide (SiOₓ such as SiO₂), among other examples. The oxynitride capping layer 140 may include an oxynitride-containing dielectric material such as silicon oxynitride (SiON), among other examples. The nitride capping layer 142 may include a nitride-containing dielectric material such as silicon nitride (SiₓN_{y} such as Si₃N₄), among other examples.

The trenches further include a plurality of air gaps 144 disposed between the bottom electrode layer 132 and the ILD layer 114b and between the bottom electrode layer 132 and the ESL 116b. Each air gap 144 is further disposed between a first additional insulator layer 146, and a second additional insulator layer 148, on opposite sides of each air gap 144. The first additional insulator layers 146 are formed on and conform to the profiles of side surfaces of the ILD layer 114b, side surfaces of the ESLs 116a, 116b, and 116c, and a top surface of the first or second bottom contact 128a or 128b in a trench. The second additional insulator layers 148 are disposed along side surfaces of portions of the insulator layer 134 and of the bottom electrode layer 132 in a trench. The air gaps 144 are enclosed (e.g., covered by) portions of the top electrode layer 136 disposed between top portions of the first and second additional insulator layers 146 and 148. The insulator layers 134 and the second additional insulator layers 148 physically and electrically isolate the top electrode layer 136 from the bottom electrode layer 132.

In some implementations, an air gap in a trench may be a single continuous air gap formed around the bottom electrode layer 132 and between the bottom electrode layer 132 and the ILD layer 114b. In this case, although depicted as separate air gaps 144 on each side of the bottom electrode layer 132 in a trench in the cross-sectional view in FIG. 1B, the air gaps 144 may instead be portions of a single continuous air gap formed around the bottom electrode layer 132 and between the bottom electrode layer 132 and the ILD layer 114b in the trench. The continuous air gap may be apparent when viewing each trench from a top-down view (e.g., “bird's eye” view). Alternatively, the air gaps 144 may be multiple (e.g., two or more) discontinuous air gaps formed between different sides of the bottom electrode layer 132 and the ILD layer 114b in a trench.

In some implementations, the first additional insulator layers 146 and the second additional insulator layers 148 include a silicon oxide (e.g., SiO₂), an oxynitride containing dielectric material such as silicon oxynitride (SiON), a silicon nitride (e.g., SiN), a silicon carbonitride (e.g., SiCN), a silicon carbide (e.g., SiC), a silicon oxycarbide (e.g., SiOC), a silicon oxycarbonitride (e.g., SiOCN), and/or other low-k dielectric materials. In some implementations, a thickness t of the first additional insulator layers 146 and the second additional insulator layers 148 may be included in the range of approximately 10 angstroms to approximately 150 angstroms. However, other values and ranges for the thickness of the first additional insulator layers 146 and the second additional insulator layers 148 are within the scope of this disclosure.

As shown in FIG. 1B, the air gaps 144 each have an L-shape, with a width W (e.g., x-direction dimension), and depth D1 (e.g., z-direction dimension). In some implementations, the width W may be included in a range of approximately 1 nanometer to approximately 30 nanometers. If the width W is greater than approximately 30 nanometers, capacitance may be significantly reduced, which may lead to decreased energy storage capacity and decreased device performance. Additionally, due to surface tension limitations for wider areas, portions of the top electrode layer 136 may penetrate beyond a top portion of the space between the first and second additional insulator layers 146 and 148, and fill in the air gaps 144. If the width is less than approximately 1 nanometer, occurrences of dielectric breakdown and/or arcing may be increased, which can cause short circuits or permanent damage to the capacitor. In addition, if the width is less than approximately 1 nanometer, residual material from manufacturing processes may remain in the gap, creating one or more defects that may affect device performance. However, other values and ranges are within the scope of the present disclosure. The width W may be substantially uniform from a top of a trench to a bottom of a trench in the z-direction. In some implementations, the ratio of the depth D1 of an air gap 144 to a total depth of a trench may be included in a range of 0.001:1 (i.e., 1:1000) to approximately 1:1. However, other values and ranges are within the scope of the present disclosure.

The dielectric constant (or relative permittivity) of the air gaps 144 is approximately 1 (e.g., a dielectric constant of air in a vacuum is 1.00, and a dielectric constant of air at normal temperature and pressure (NTP) is approximately 1.00058986). The dielectric constant of the air gaps 144 is significantly less than the dielectric constant of porous low-k or bulk dielectric materials that may be used in other capacitor structures. For example, the dielectric constant of silicon dioxide (SiO₂) is approximately 3.9. The lesser dielectric constant of the air gaps 144 in comparison to that of the porous low-k or bulk dielectric materials reduces the capacitive coupling between adjacent capacitor structures, thus suppressing cross-talk, increasing signal integrity, reducing RC delay, and reducing current leakage, leading to increased device performance and reliability.

The bottom electrode layer 132 and the insulator layer 134 on the bottom electrode layer 132 may be conformal layers that conform to the profile of the trenches and/or second additional insulator layers 148 on which the bottom electrode layer 132 is formed. For example, the bottom electrode layer 132 may conform to the profile of the second additional insulator layer 148 and the bottom surface of the trench on which the bottom electrode layer 132 is formed. The insulator layer 134 may conform to the profile of the bottom electrode layer 132 on which the insulator layer 134 is formed. The trench capacitor structure 126a further includes the top electrode layer 136 on the insulator layer 134. In some implementations, the top electrode layer 136 is a fill layer that fills in the remaining areas of the trenches. Alternatively, the top electrode layer 136 may also be a conformal layer that conforms to the profile of the layer on which the top electrode layer 136 is formed, and a dielectric plug layer or fill layer is further included in the remaining areas of the trenches.

The bottom electrode layer 132, the insulator layer 134, and the top electrode layer 136 correspond to an MIM structure of the trench capacitor structure 126a. Thus, the trench capacitor structure 126a may also be referred to as an MIM capacitor structure or, generally, as a semiconductor structure. The bottom electrode layer 132 (also referred to as a capacitor bottom metal (CBM)) and the top electrode layer 136 (also referred to as a capacitor top metal (CTM)) may each include one or more electrically conductive metals, one or more electrically conductive metal-containing materials, one or more electrically conductive ceramic materials, and/or other types of electrically conductive materials. Examples include tungsten (W), cobalt (Co), ruthenium (Ru), titanium (Ti), aluminum (Al), copper (Cu), gold (Au), titanium nitride (TiN), and/or tantalum nitride (TaN), among other examples. In some implementations, the bottom electrode layer 132 and the top electrode layer 136 include the same material or the same material composition. In some implementations, the bottom electrode layer 132 and the top electrode layer 136 include different materials or different material compositions.

The insulator layer 134 may include one or more electrically insulating materials. In some implementations, the insulator layer 134 includes one or more low-k dielectric materials such as silicon oxide (SiOₓ such as SiO₂). Additionally and/or alternatively, the insulator layer 134 may include one or more high-k dielectric materials such as zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), and/or hafnium oxide (HfOₓ such as HfO₂), among other examples. In some implementations, the insulator layer 134 is a multiple-layer stack that includes a plurality of dielectric layers. For example, the insulator layer 134 may include a ZrO₂/Al₂O₃/ZrO₂ (ZAZ) layer stack.

In some implementations, the trench capacitor structure 126a includes a plurality of trenches, and the MIM structure of the trench capacitor structure 126a (e.g., the bottom electrode layer 132, the insulator layer 134, and the top electrode layer 136) may extend along the sidewalls and bottom surfaces of the plurality of trenches, and the top electrode layer 136 over the trenches, and on the ESL 116c between the plurality of trenches. The trenches may be laterally arranged and spaced apart by a distance in the x-direction. In this way, including a plurality of trenches in the trench capacitor structure 126a enables the length (and therefore the area) of the MIM structure of the trench capacitor structure 126a (e.g., of the bottom electrode layer 132, the insulator layer 134, and the top electrode layer 136) to be extended, thereby increasing the capacitance of the trench capacitor structure 126a.

The capping layers 138-142 may be used as a self-aligned mask when etching the top electrode layer 136 to define the MIM structure of the trench capacitor structure 126a. An ILD layer 114c is disposed on the capping layers 138-142, and the top contact 130 is disposed through the ILD layer 114c and the capping layers 138-142 to contact the top electrode layer 136.

FIG. 1C illustrates a trench capacitor structure 126b. The trench capacitor structure 126b is similar to the trench capacitor structure 126a. For example, similar to the trench capacitor structure 126a, the trench capacitor structure 126b includes components 114a-114c, 116a-116c, 128a, 128b, 130, and 132-142. The trench capacitor structure 126b further includes air gaps 150, first additional insulator layers 152, and second additional insulator layers 154. The first additional insulator layers 152 are similar to the first additional insulator layers 146, except that the first additional insulator layers 152 do not have an L-shape with a bottom portion on a first or second bottom contact 128a or 128b. The second additional insulator layers 154 are similar to the second additional insulator layers 148, except that the second additional insulator layers 154 extend to land on the first or second bottom contact 128a or 128b. As a result, instead of having an L-shape like the air gaps 144, the air gaps 150 of the trench capacitor structure 126b have a straight profile from top to bottom portions thereof.

Similar to the trench capacitor structure 126a, in the trench capacitor structure 126b, although depicted as separate air gaps 150 on each side of the bottom electrode layer 132 in a trench in the cross-sectional view in FIG. 1C, the air gaps 150 may instead be portions of a single continuous air gap formed around the bottom electrode layer 132 and between the bottom electrode layer 132 and the ILD layer 114b in the trench. The continuous air gap may be apparent when viewing each trench from a top-down view (e.g., “bird's eye” view). Alternatively, the air gaps 150 may be multiple (e.g., two or more) discontinuous air gaps formed between different sides of the bottom electrode layer 132 and the ILD layer 114b in a trench.

Similar to the air gaps 144, the air gaps 150 each have a width W (e.g., x-direction dimension), and depth D2 (e.g., z-direction dimension). In some implementations, the width W may be included in a range of approximately 1 nanometer to approximately 30 nanometers. If the width W is greater than approximately 30 nanometers, capacitance may be significantly reduced, which may lead to decreased energy storage capacity and decreased device performance. Additionally, due to surface tension limitations for wider areas, portions of the top electrode layer 136 may penetrate beyond a top portion of the space between the first and second additional insulator layers 146 and 148, and fill in the air gaps 150. If the width is less than approximately 1 nanometer, occurrences of dielectric breakdown and/or arcing may be increased, which can cause short circuits or permanent damage to the capacitor. In addition, if the width is less than approximately 1 nanometer, residual material from manufacturing processes may remain in the gap, creating one or more defects that may affect device performance. However, other values and ranges are within the scope of the present disclosure. The width W may be substantially uniform from a top of a trench to a bottom of a trench in the z-direction. In some implementations, the ratio of the depth D2 of an air gap 150 to a total depth of a trench may be included in a range of 0.001:1 to approximately 1:1. However, other values and ranges are within the scope of the present disclosure.

Similar to the first additional insulator layers 146 and the second additional insulator layers 148, a thickness t of the first additional insulator layers 152 and the second additional insulator layers 154 of the trench capacitor structure 126b may be included in the range of approximately 10 angstroms to approximately 150 angstroms. However, other values and ranges for the thickness of the first additional insulator layers 152 and the second additional insulator layers 154 of the trench capacitor structure 126b are within the scope of this disclosure. The insulator layers 134 and the second additional insulator layers 154 physically and electrically isolate the top electrode layer 136 from the bottom electrode layer 132.

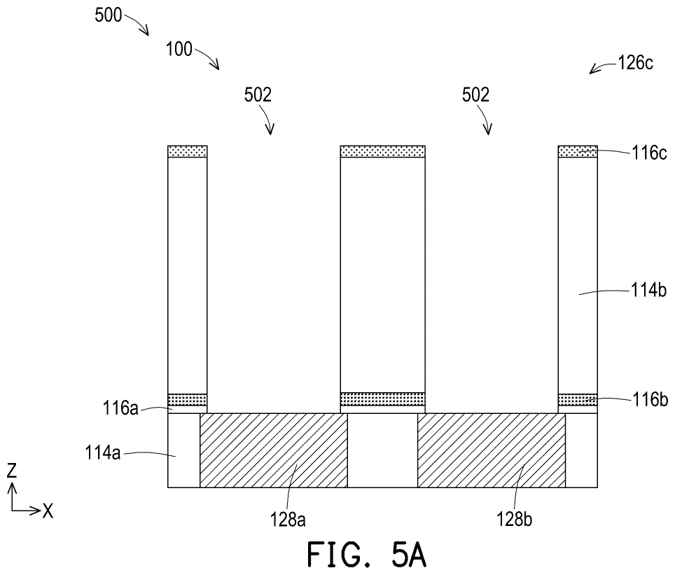

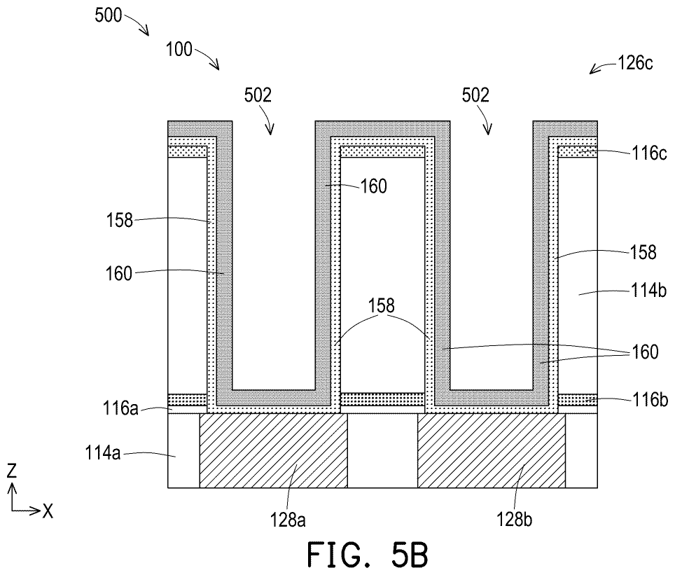

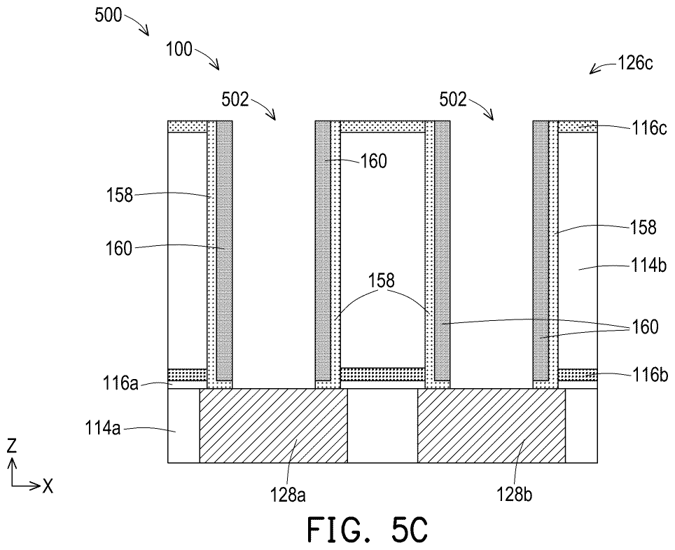

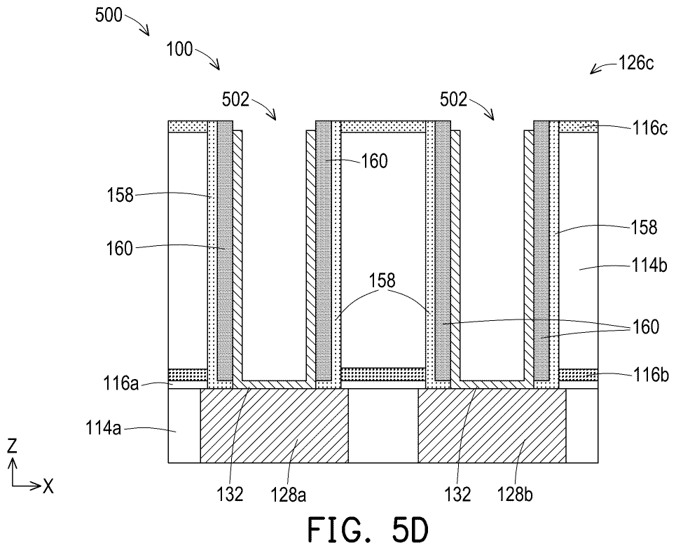

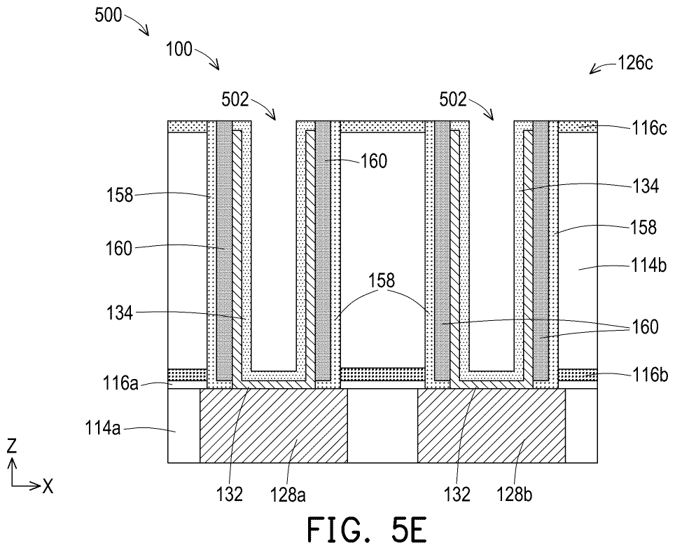

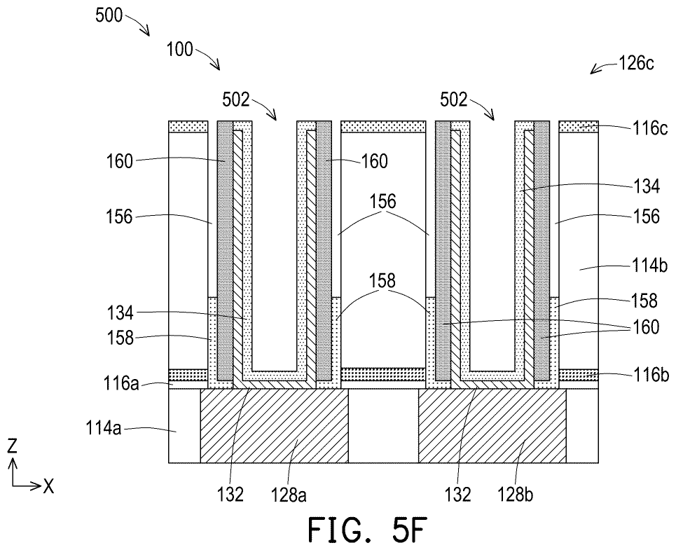

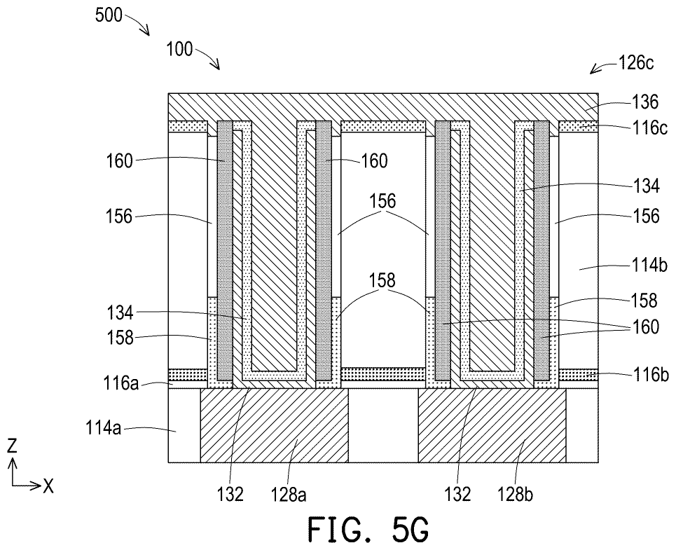

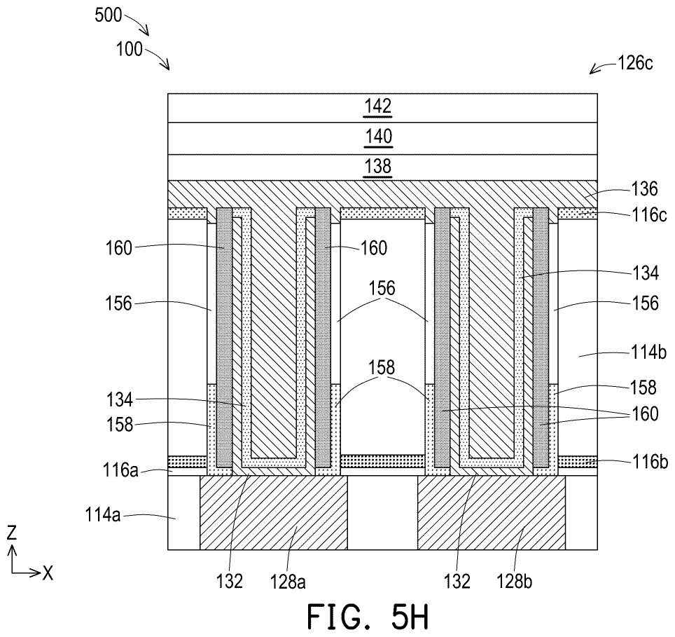

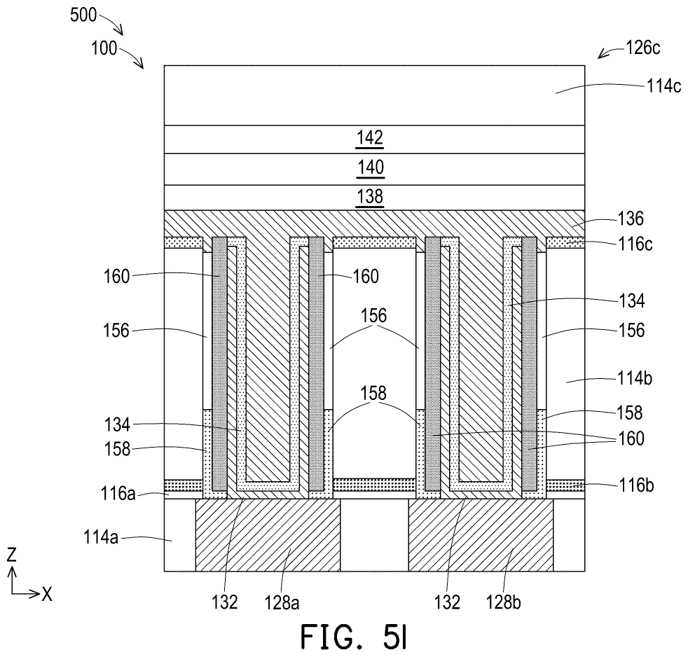

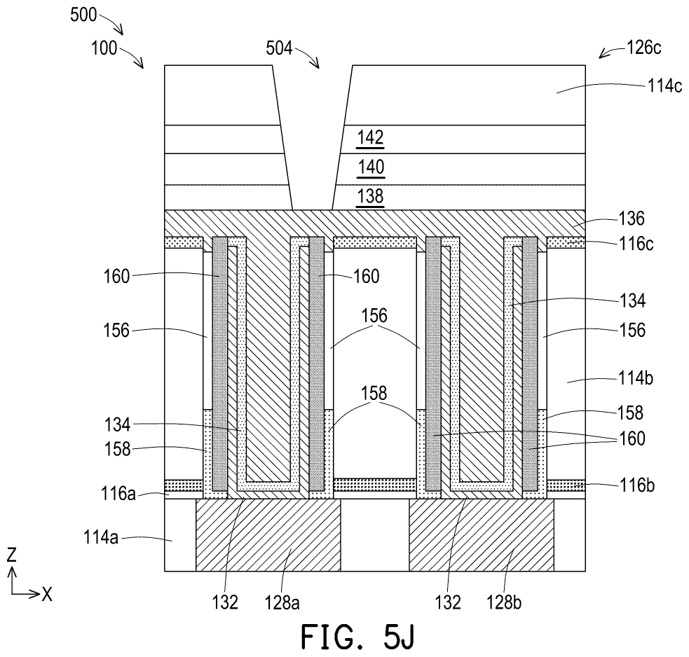

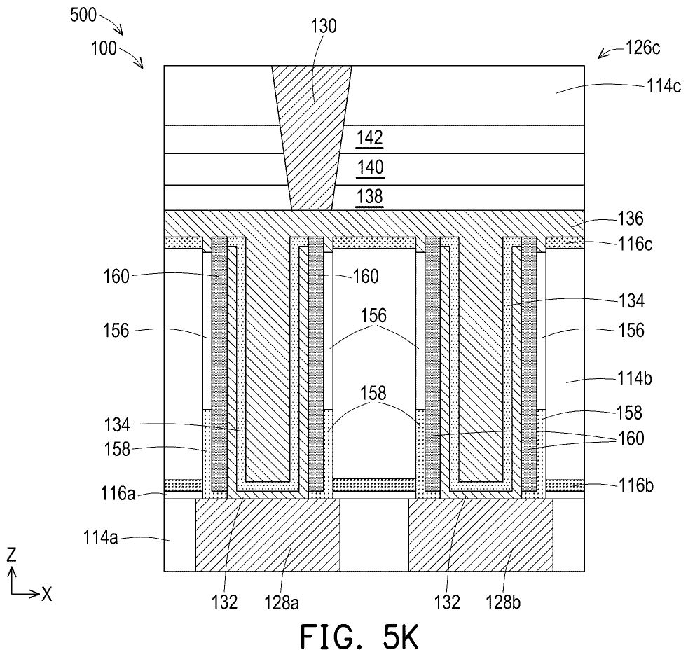

FIG. 1D illustrates a trench capacitor structure 126c. The trench capacitor structure 126c is similar to the trench capacitor structure 126a. For example, similar to the trench capacitor structure 126a, the trench capacitor structure 126c includes components 114a-114c, 116a-116c, 128a, 128b, 130, and 132-142. The trench capacitor structure 126c further includes air gaps 156, sacrificial layers 158, and additional insulator layers 160. The air gaps 156 are similar to the air gaps 144, except that each of the air gaps 156 is disposed over a sacrificial layer 158. Each sacrificial layer 158 is located between an additional insulator layer 160 and the ILD layer 114b and ESL 116b. As explained in more detail in connection with FIG. 5F, a portion of each sacrificial layer 158 is removed to form the air gaps 156. In addition, instead of being disposed between two additional insulator layers (e.g., first and second additional insulator layers 146 and 148), each of the air gaps 156 are disposed between an additional insulator layer 160 and the ILD layer 114b and ESL 116b. Part of each sacrificial layer 158 is disposed on a first or second bottom contact 128a or 128b, between the ESL 116a and a portion of the bottom electrode layer 132, and under an additional insulator layer 160. The sacrificial layers 158 each have an L-shape.

Similar to the trench capacitor structures 126a and 126b, in the trench capacitor structure 126c, although depicted as separate air gaps 156 on each side of the bottom electrode layer 132 in a trench in the cross-sectional view in FIG. 1D, the air gaps 156 may instead be portions of a single continuous air gap formed around the bottom electrode layer 132 and between the bottom electrode layer 132 and the ILD layer 114b in the trench. The continuous air gap may be apparent when viewing each trench from a top-down view (e.g., “bird's eye” view). Alternatively, the air gaps 156 may be multiple (e.g., two or more) discontinuous air gaps formed between different sides of the bottom electrode layer 132 and the ILD layer 114b in a trench.

In some implementations, the sacrificial layers 158 include an aluminum oxynitride (e.g., AlON), an aluminum nitride (e.g., AlN), an aluminum oxide (e.g., AlO), a hafnium oxide (e.g., HfO), a zirconium oxide (e.g., ZrO), an indium zirconium oxide (e.g., InZrO), a hafnium zirconium oxide (e.g., HfZrO), a titanium oxide (e.g., TiO), a titanium aluminum oxide (e.g. TiAlO), a tantalum oxide (e.g., Ta₂O₅), and/or other materials. The additional insulator layers 160 may include the same or similar materials as the first and second additional insulator layers 146 and 148.

Similar to the air gaps 144, the air gaps 156 each have a width W (e.g., x-direction dimension), and depth D3 (e.g., z-direction dimension). In some implementations, the width W may be included in a range of approximately 1 nanometer to approximately 10 nanometers. If the width W is greater than approximately 10 nanometers, capacitance may be significantly reduced, which may lead to decreased energy storage capacity and decreased device performance. Additionally, due to surface tension limitations for wider areas, portions of the top electrode layer 136 may penetrate beyond a top portion of the air gaps 156, and fill in the air gaps 156. If the width is less than approximately 1 nanometer, occurrences of dielectric breakdown and/or arcing may be increased, which can cause short circuits or permanent damage to the capacitor. In addition, if the width is less than approximately 1 nanometer, residual material from manufacturing processes may remain in the gap, creating one or more defects that may affect device performance. However, other values and ranges are within the scope of the present disclosure. The width W may be substantially uniform from a top of a trench to a bottom of a trench in the z-direction. In some implementations, the ratio of the depth D3 of an air gap 156 to a total depth of a trench may be included in a range of 0.001:1 to approximately 0.9:1. However, other values and ranges are within the scope of the present disclosure.

A thickness t1 of the additional insulator layers 160 of the trench capacitor structure 126c may be included in the range of approximately 10 angstroms to approximately 150 angstroms. However, other values and ranges for the thickness of the additional insulator layers 160 of the trench capacitor structure 126c are within the scope of this disclosure. The insulator layers 134 and the additional insulator layers 160 physically and electrically isolate the top electrode layer 136 from the bottom electrode layer 132. A thickness t2 of the sacrificial layers 158 of the trench capacitor structure 126c may be included in the range of approximately 10 angstroms to approximately 200 angstroms. However, other values and ranges for the thickness of the additional insulator layers 160 of the trench capacitor structure 126c are within the scope of this disclosure.

FIG. 1E illustrates a trench capacitor structure 126d. The trench capacitor structure 126d is similar to the trench capacitor structure 126a. For example, similar to the trench capacitor structure 126a, the trench capacitor structure 126d includes components 114a-114c, 116a-116c, 128a, 128b, 130, and 132-142. The trench capacitor structure 126d further includes air gaps 162 and additional insulator layers 164. The air gaps 162 are similar to the air gaps 144, except that each of the air gaps 162 is disposed over a portion of the additional insulator layer 164, which is disposed on a portion of the bottom electrode layer 132. In addition, unlike the straight profile of the second additional insulator layer 148, the additional insulator layer 164 has a curved and/or angular profile, with different segments 164a, 164b, 164c at different angles with respect to each other. As a result, the width W of the air gaps 162 varies based on the angle and/or orientation of the segments 164b and 164c. For example, the width W of the air gaps 162 decreases in the downward z-direction. The additional insulator layers 164 may include the same or similar materials as the first and second additional insulator layers 146 and 148.

Similar to the trench capacitor structures 126a, 126b, and 126c, in the trench capacitor structure 126d, although depicted as separate air gaps 162 on each side of the bottom electrode layer 132 in a trench in the cross-sectional view in FIG. 1E, the air gaps 162 may instead be portions of a single continuous air gap formed around the bottom electrode layer 132 and between the bottom electrode layer 132 and the ILD layer 114b in the trench. The continuous air gap may be apparent when viewing each trench from a top-down view (e.g., “bird's eye” view). Alternatively, the air gaps 162 may be multiple (e.g., two or more) discontinuous air gaps formed between different sides of the bottom electrode layer 132 and the ILD layer 114b in a trench.

The profile of a top portion of the bottom electrode layer 132 conforms to the profile of the segments 164a, 164b, and 164c of the additional insulator layer 164. A profile of a bottom portion of the bottom electrode layer 132 conforms to the profile of the side surfaces of the ILD layer 114b and the ESLs 116a and 116b in a trench, and to a top surface of the first or second bottom contact 128a or 128b at the bottom of the trench. The insulator layer 134 on the bottom electrode layer 132 conforms to the profile of the bottom electrode layer 132, and the top electrode layer 136 on the insulator layer 134 conforms to the profile of the insulator layer 134.

Similar to the air gaps 144, the air gaps 162 each have a width W (e.g., x-direction dimension), and depth D4 (e.g., z-direction dimension). In some implementations, the width W may be included in a range of approximately 1 nanometer to approximately 10 nanometers. If the width W is greater than approximately 10 nanometers, capacitance may be significantly reduced, which may lead to decreased energy storage capacity and decreased device performance. Additionally, due to surface tension limitations for wider areas, portions of the top electrode layer 136 may penetrate beyond a top portion of the air gaps 162, and fill in the air gaps 162. If the width is less than approximately 1 nanometer, occurrences of dielectric breakdown and/or arcing may be increased, which can cause short circuits or permanent damage to the capacitor. In addition, if the width is less than approximately 1 nanometer, residual material from manufacturing processes may remain in the gap, creating one or more defects that may affect device performance. However, other values and ranges are within the scope of the present disclosure. In some implementations, the ratio of the depth D4 of an air gap 162 to a total depth of a trench may be included in a range of 0.001:1 to approximately 0.5:1. However, other values and ranges are within the scope of the present disclosure.

A thickness t3 of the additional insulator layers 164 of the trench capacitor structure 126d may be included in the range of approximately 10 angstroms to approximately 150 angstroms. However, other values and ranges for the thickness of the additional insulator layers 164 of the trench capacitor structure 126d are within the scope of this disclosure. The insulator layers 134 and the additional insulator layers 164 physically and electrically isolate the top electrode layer 136 from the bottom electrode layer 132.

As indicated above, FIGS. 1A-1E are provided as an example. Other examples may differ from what is described with regard to FIGS. 1A-1E.

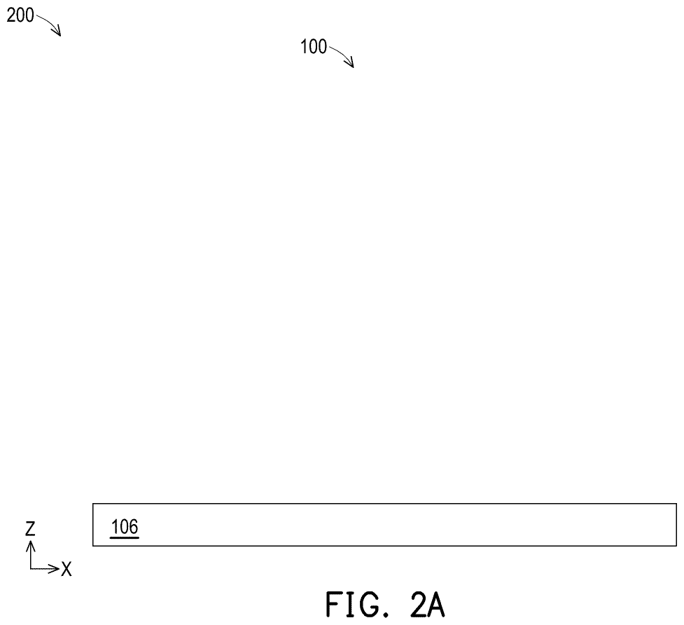

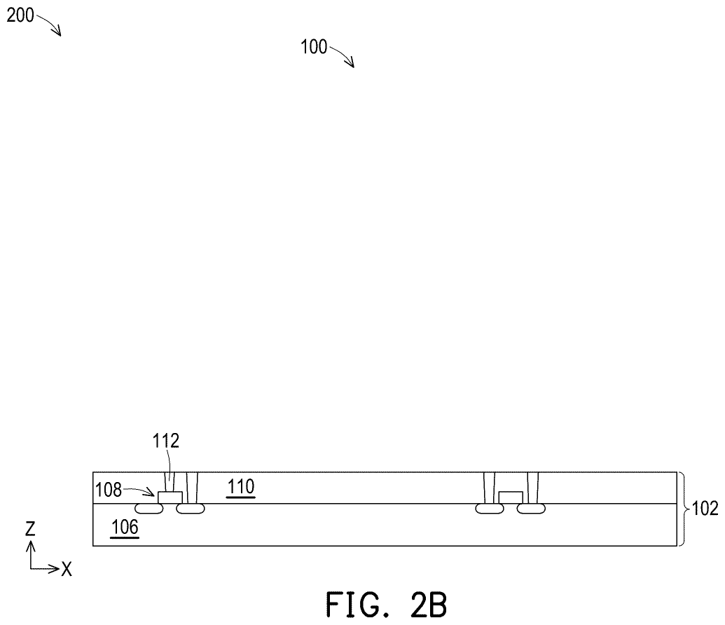

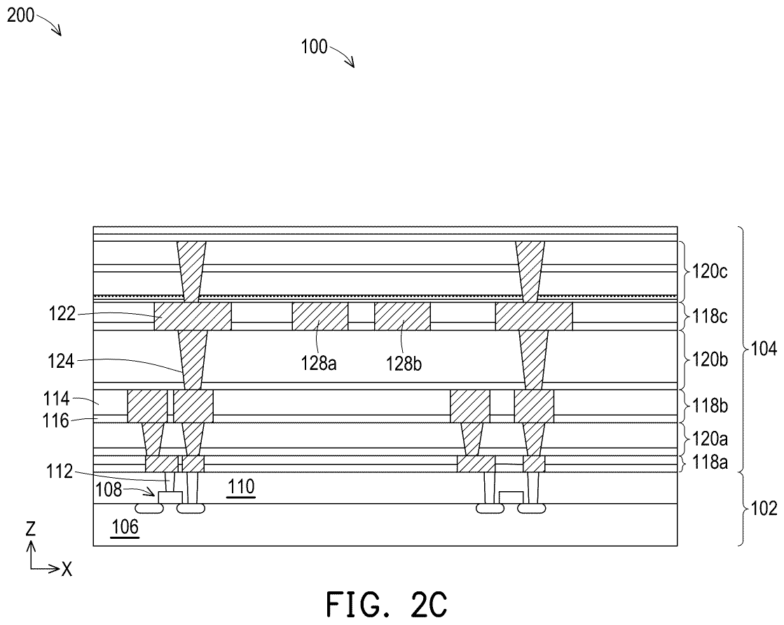

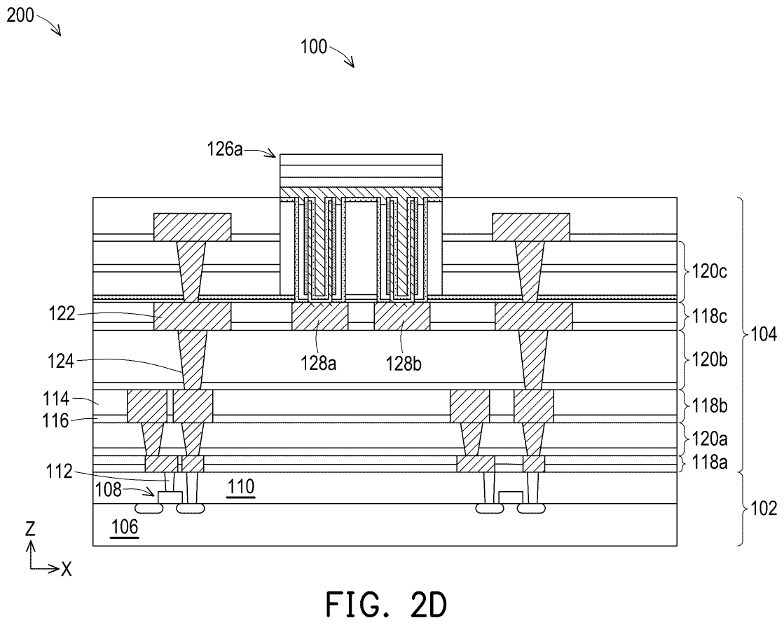

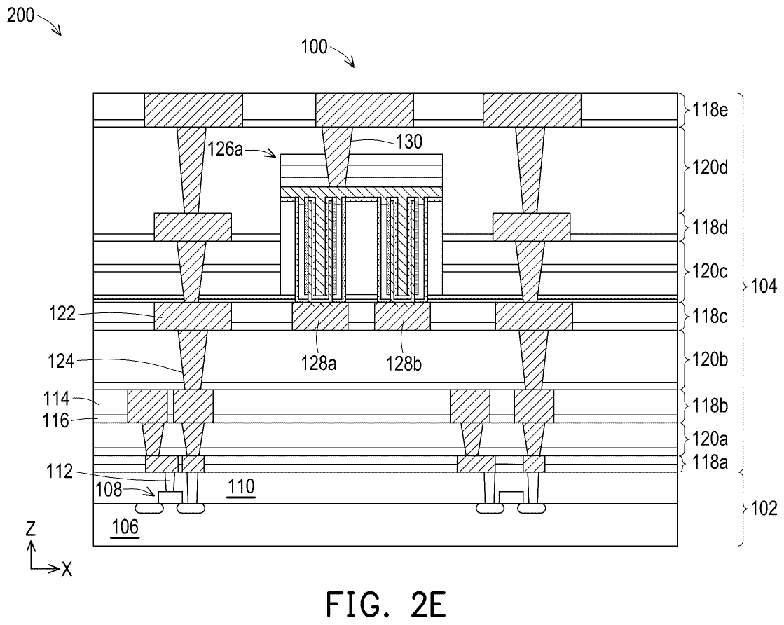

FIGS. 2A-2E are diagrams of an example implementation 200 of forming the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

Turning to FIG. 2A, the substrate 106 is provided. The substrate 106 may be provided in the form of a semiconductor wafer such as a silicon (Si) wafer, an SOI wafer, and/or another type of semiconductor work piece. The semiconductor device 100 may be formed on the semiconductor wafer with other semiconductor devices.

As shown in FIG. 2B, the integrated circuit devices 108 may be formed in and/or on the substrate 106 in the device layer 102 of the semiconductor device 100. One or more semiconductor processing tools may be used to form one or more portions of the integrated circuit devices 108. For example, an ion implantation tool may be used to dope one or more regions in the substrate 106 with one or more types of dopants to form well regions, implant regions, and/or other types of doped regions in the substrate 106 for the integrated circuit devices 108. As another example, a deposition tool may be used to perform various deposition operations to deposit layers and/or structures of the integrated circuit devices 108, and/or to deposit photoresist layers for etching the substrate 106 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 106 and/or portions of the deposited layers to form the integrated circuit devices 108. As another example, a planarization tool may be used to planarize portions of the integrated circuit devices 108. As another example, a plating tool may be used to deposit metal structures and/or layers of the integrated circuit devices 108.

As further shown in FIG. 2B, a deposition tool is used to deposit the dielectric layer 110 over and/or on the substrate 106 and over and/or on the integrated circuit devices 108. A deposition tool may be used to deposit the dielectric layer 110 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the dielectric layer 110 after the dielectric layer 110 is deposited.

As further shown in FIG. 2B, the contacts 112 of the integrated circuit devices 108 may be formed through the dielectric layer 110. The contacts 112 may be formed in recesses in the dielectric layer 110. In some implementations, a pattern in a photoresist layer is used to etch the dielectric layer 110 to form the recesses. In these implementations, a deposition tool may be used to form the photoresist layer on the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 110 based on a pattern to form the recesses.

The contacts 112 may be formed in the recesses. In some implementations, a contact 112 (e.g., a gate contact) is formed on a gate structure of an integrated circuit device 108. In some implementations, a contact 112 (e.g., a source/drain contact) is formed on a source/drain region of an integrated circuit device 108. A deposition tool may be used to deposit the material of the contacts 112 in the recesses using a CVD technique, a PVD technique, an ALD technique, an electroplating technique, and/or another suitable deposition technique. The material of the contacts 112 may be deposited in one or more deposition operations. In some implementations, a seed layer is first deposited, and the material of the contacts 112 is deposited on the seed layer. In some implementations, a planarization tool is used to perform a planarization operation (e.g., a CMP operation) to planarize the contacts 112 after the contacts 112 are deposited such that the tops of the contacts 112 are approximately co-planar with the top of the dielectric layer 110.

As shown in FIG. 2C, a first portion of the interconnect layer 104 of the semiconductor device 100 is formed above the dielectric layer 110. One or more deposition tools are used to deposit alternating layers of ILD layers 114 and ESLs 116 in the first portion of the interconnect layer 104 of the semiconductor device 100. In this way, the ILD layers 114 and ESLs 116 may be arranged in the z-direction in the semiconductor device 100. One or more deposition tools may be used to deposit each of the ILD layers 114 and each of the ESLs 116 using a PVD technique, an ALD technique, a CVD technique, an oxidation technique, and/or another suitable deposition technique. In some implementations, a planarization tool may be used to planarize the ILD layers 114 and/or the ESLs 116 after the ILD layers 114 and/or the ESLs 116 are deposited.

As further shown in FIG. 2C, a deposition tool, an exposure tool, a developer tool, an etch tool, a planarization tool, a plating tool, and/or another semiconductor processing tool may be used to perform various operations to form the metallization structures 122 and to form the interconnect structures 124 in the first portion of the interconnect layer 104 of the semiconductor device 100. The first bottom contact 128a and the second bottom contact 128b of the trench capacitor structure 126a-126d may also be formed in the first portion of the interconnect layer 104.

In some implementations, the first portion of the interconnect layer 104 may be formed in a plurality of layers. For example, an ILD layer 114 and an ESL 116 may be formed (e.g., using one or more deposition tools and/or one or more planarization tools), recesses may be formed in and/or through the ILD layer 114 and the ESL 116 (e.g., using an exposure tool, a developer tool, and/or an etch tool), and the layer 118a (e.g., the M0 layer) of metallization structures 122 may be formed in the ILD layer 114 and the ESL 116 (e.g., using one or more deposition tools and/or one or more planarization tools). Another ILD layer 114 and another ESL 116 may be formed, and the layer 120a (e.g., the V0 layer) of interconnect structures 124 may be formed in the ILD layer 114 and the ESL 116. The layers 118b, 118c, 120b, and 120c may be formed in a similar manner.

One or more deposition tools may be used to deposit the metallization structures 122, the interconnect structures 124, and/or the first bottom contact 128a and the second bottom contact 128b using a PVD technique, an ALD technique, a CVD technique, an electroplating technique (e.g., an electro-chemical plating technique), and/or another suitable deposition technique. In some implementations, a planarization tool may be used to planarize the metallization structures 122, the interconnect structures 124, and/or the first bottom contact 128a and the second bottom contact 128b after the metallization structures 122, the interconnect structures 124, and/or the first bottom contact 128a and the second bottom contact 128b are deposited.

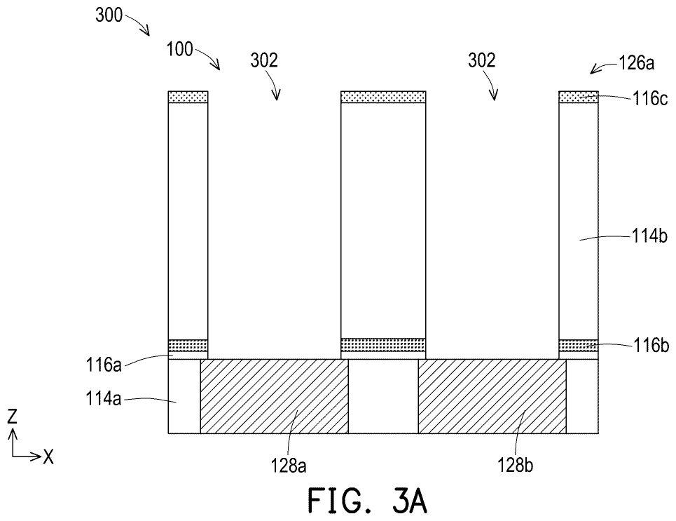

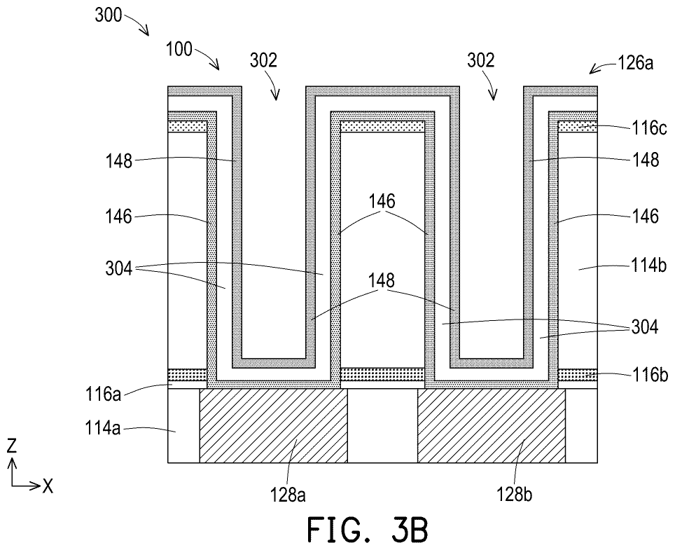

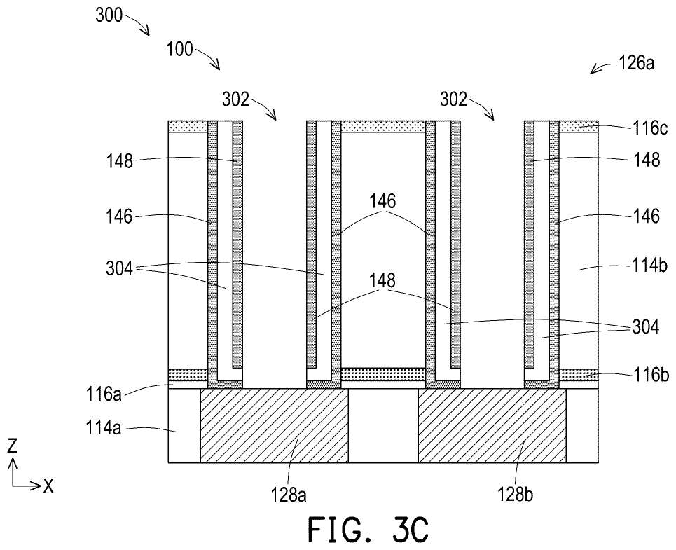

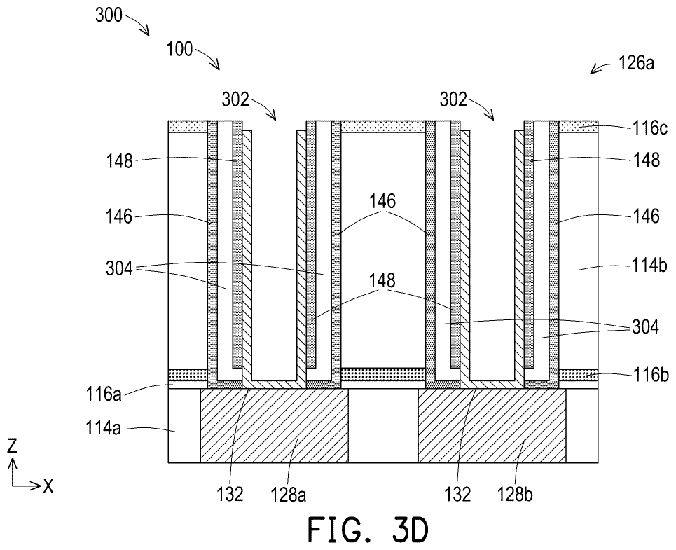

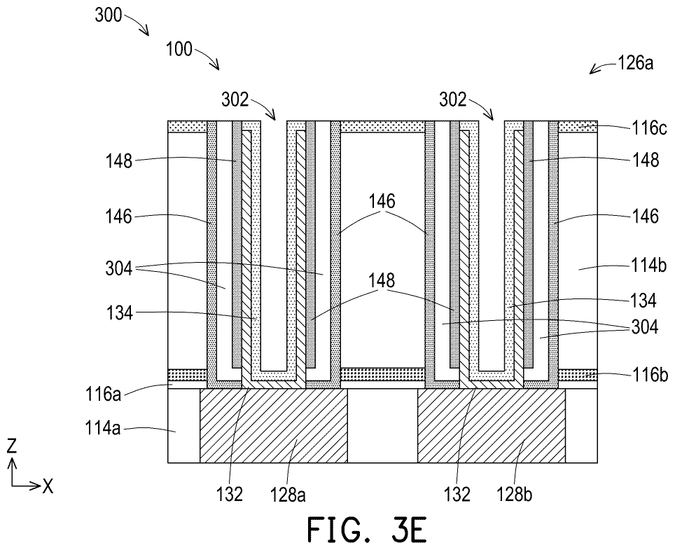

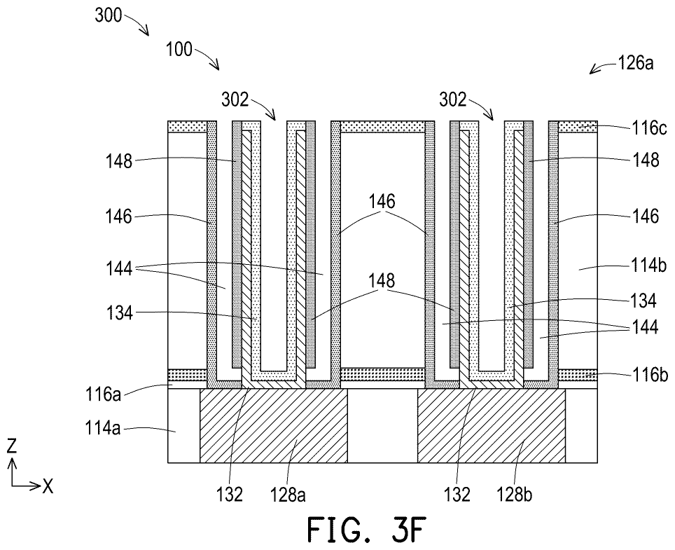

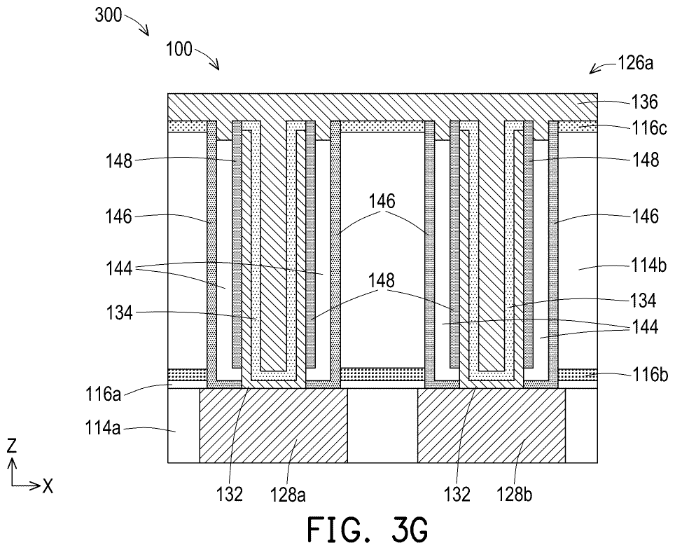

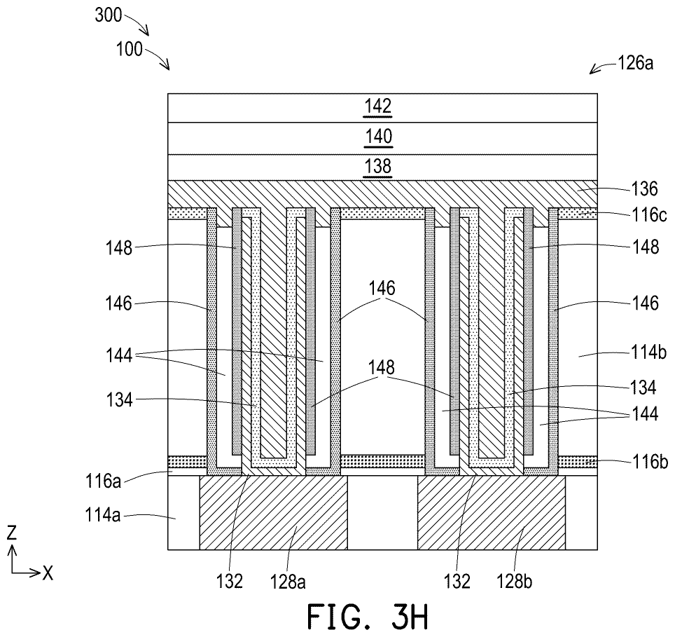

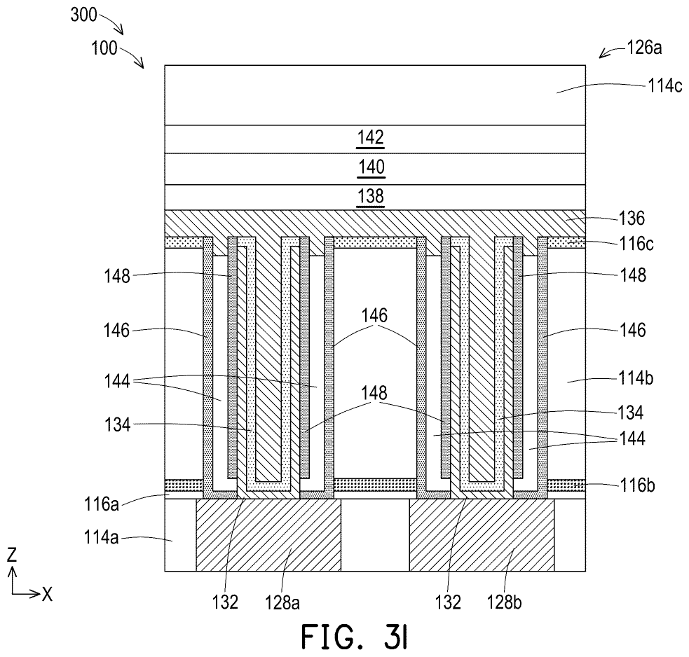

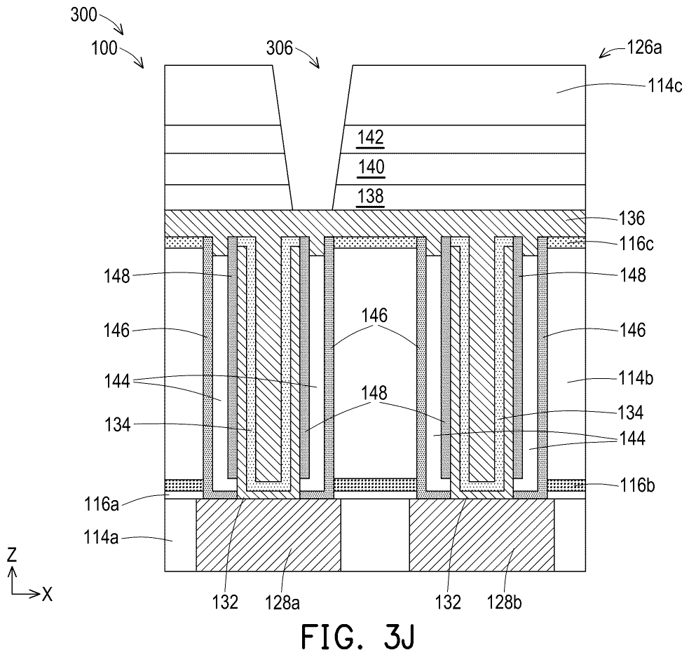

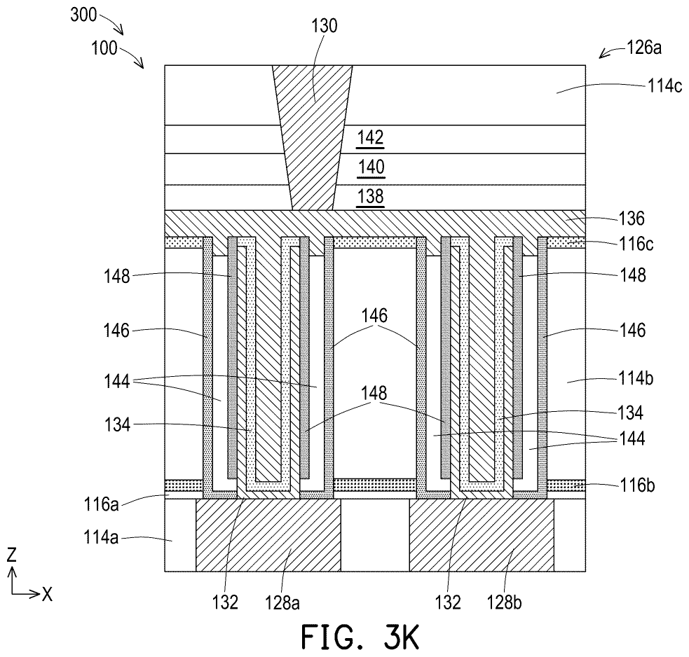

As shown in FIG. 2D, a trench capacitor structure 126a may be formed in one or more dielectric layers in the interconnect layer 104. The trench capacitor structure 126a may be formed such that the trenches of the trench capacitor structure 126a land on the first bottom contact 128a and the second bottom contact 128b in the interconnect layer 104. An example process for forming the trench capacitor structure 126a is illustrated and described in connection with FIGS. 3A-3K.

As shown in FIG. 2E, a second portion of the interconnect layer 104 of the semiconductor device 100 is formed above the first portion of the interconnect layer 104, including above the trench capacitor structure 126a. The second portion of the interconnect layer 104 may be formed in a similar manner to the first portion of the interconnect layer 104 as described in connection with FIG. 2C. The top contact 130 of the trench capacitor structure 126a may be formed in the second portion of the interconnect layer 104.

As indicated above, FIGS. 2A-2E are provided as an example. Other examples may differ from what is described with regard to FIGS. 2A-2E.

FIGS. 3A-3K are diagrams of an example implementation 300 of forming a trench capacitor structure 126a described herein. In some implementations, one or more of the semiconductor processing operations described in connection with FIGS. 3A-3K may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 3A-3K may be performed as part of the process for forming the semiconductor device 100 described in connection with FIGS. 2A-2E.

As shown in FIG. 3A, an etch operation is performed to etch through the ILD layer 114b and through the ESLs 116a, 116b, and 116c to form the trenches 302 of the trench capacitor structure 126a. The etch operation may include a gas-based etch operation in which a gas-based etchant is used. An etch tool may be used to perform the gas-based etch operation.

The gas-based etchant that is used to etch the ILD layer 114b and the ESLs 116a, 116b, and 116c may include a fluorine-based gas etchant. The fluorine-based etchant may include a carbon fluoride-based (CFₓ) gas etchant such as a carbon tetrafluoride (CF₄) gas etchant.

In some implementations, a plurality of etch operations (e.g., a plurality of gas-based etch operations using the fluorine-based etchant) are performed to form the trenches 302 of the trench capacitor structure 126a. For example, a first etch operation (referred to as a “main etch” operation) may be performed to form the trenches 302 to the ESL 116a. In other words, etching in the first etch operation stops at the ESL 116a such that the ESL 116a remains between the bottom of the trenches 302 and the underlying first bottom contact 128a and second bottom contact 128b. The ESL 116a may be kept over the first bottom contact 128a and second bottom contact 128b to prevent the first bottom contact 128a and second bottom contact 128b from being exposed to oxygen and other contaminants that might otherwise result in oxidation of the first bottom contact 128a and second bottom contact 128b. After the first etch operation, the trenches 302 may have tapered sidewalls, resulting in the lateral width of the trenches 302 decreasing from the tops of the trenches 302 to the bottoms of the trenches.

A second etch operation (referred to as an “over etch” operation) may be performed after the first etch operation to shape the bottom portions of the trenches 302. In particular, the second etch operation may be performed to increase the verticality of the sidewalls of the trenches 302, thereby lessening the taper in the sidewalls of the trenches 302. A third etch operation (referred to as a “linear removal” etch operation) may be performed to etch through the ESL 116a at the bottom of the trenches 302 to extend the trenches 302 through the ESL 116a and to the underlying first bottom contact 128a and second bottom contact 128b. Thus, the first bottom contact 128a and second bottom contact 128b are exposed through the trenches 302 after the third etch operation. The third etch operation may be performed using a fluorine-based etchant such as a carbon fluoride-based (CFₓ such as CF₄) gas etchant.

As shown in FIG. 3B, the first additional insulator layer 146 may be deposited on the sidewalls and on the bottom surfaces of the trenches 302. The bottom surfaces of the trenches 302 correspond to the top surfaces of the first bottom contact 128a and second bottom contact 128b, and thus the first additional insulator layer 146 may be in physical contact with the top surfaces of the first bottom contact 128a and second bottom contact 128b. The first additional insulator layer 146 may also be deposited on the top surface of the ESL 116c between adjacent trenches 302 such that the first additional insulator layer 146 may be in physical contact with the top surface of the ESL 116c. In some implementations, a deposition tool is used to conformally deposit the first additional insulator layer 146 such that the first additional insulator layer 146 conforms to the profile of the trenches 302. In some implementations, a conformal CVD technique and/or an ALD technique is used to deposit the first additional insulator layer 146.

As further shown in FIG. 3B, a sacrificial layer 304 may be deposited on the first additional insulator layer 146. Thus, the sacrificial layer 304 is deposited on the sidewalls and on the bottom surfaces (which correspond to the top surface of the first bottom contact 128a and second bottom contact 128b) of the trenches 302. The sacrificial layer 304 may also be deposited on the top surface of the ESL 116c between adjacent trenches 302. In some implementations, a deposition tool is used to conformally deposit the sacrificial layer 304 such that the sacrificial layer 304 conforms to the profile of the trenches 302. In some implementations, a conformal CVD technique and/or an ALD technique is used to deposit the sacrificial layer 304. The sacrificial layer 304 may include a silicon oxide (e.g., SiO₂), an oxynitride containing dielectric material such as silicon oxynitride (SiON), a silicon nitride (e.g., SiN), a silicon carbonitride (e.g., SiCN), and/or other low-k dielectric materials.

As further shown in FIG. 3B, the second additional insulator layer 148 may be deposited on the sacrificial layer 304. Thus, the second additional insulator layer 148 is deposited on the sidewalls and on the bottom surfaces (which correspond to the top surfaces of the first bottom contact 128a and second bottom contact 128b) of the trenches 302. The second additional insulator layer 148 may also be deposited on the top surface of the ESL 116c between adjacent trenches 302. In some implementations, a deposition tool is used to conformally deposit the second additional insulator layer 148 such that the second additional insulator layer 148 conforms to the profile of the trenches 302. In some implementations, a conformal CVD technique and/or an ALD technique is used to deposit the second additional insulator layer 148.

As shown in FIG. 3C, portions of the stacked arrangement of the first additional insulator layer 146, the sacrificial layer 304, and the second additional insulator layer 148 are removed in an etching operation. In some implementations, a masking layer may be formed on the second additional insulator layer 148, and an etch tool may be used to etch the masking layer based on a pattern in a photoresist layer to transfer the pattern to the masking layer. The resulting patterned masking layer may cover portions of the stacked arrangement of the first additional insulator layer 146, the sacrificial layer 304, and the second additional insulator layer 148 that are to remain, and expose portions of the stacked arrangement of the first additional insulator layer 146, the sacrificial layer 304, and the second additional insulator layer 148 that are to be removed. In some implementations, the etch operation to remove the portions of the stacked arrangement of the first additional insulator layer 146, the sacrificial layer 304, and the second additional insulator layer 148 based on the pattern in the masking layer includes a dry etch operation (e.g., a plasma-based etch operation, a gas-based etch operation) using oxygen gas, hydrogen gas, hydrocarbon-containing gases, and/or fluorine-containing gases.

As shown in FIG. 3D, the bottom electrode layers 132 may be deposited in the trenches 302 on exposed side surfaces of the remaining portions of the stacked arrangement of the first additional insulator layer 146, the sacrificial layer 304, and the second additional insulator layer 148. The bottom electrode layers 132 are further deposited on the bottom surfaces (which correspond to the top surfaces of the first bottom contact 128a and second bottom contact 128b) of the trenches 302. The bottom surfaces of the trenches 302 correspond to the top surfaces of the first bottom contact 128a and second bottom contact 128b, and thus the bottom electrode layers 132 may be in physical contact with the top surfaces of the first bottom contact 128a and second bottom contact 128b. In some implementations, a deposition tool is used to conformally deposit the bottom electrode layers 132 in the trenches 302 such that the bottom electrode layers 132 conform to the profile of the trenches 302, including the exposed side surfaces of the remaining portions of the stacked arrangement of the first additional insulator layer 146, the sacrificial layer 304, and the second additional insulator layer 148, and the exposed top surfaces of the first bottom contact 128a and second bottom contact 128b. In some implementations, a conformal CVD technique and/or an ALD technique is used to deposit the bottom electrode layers 132.

As shown in FIG. 3E, the insulator layers 134 may be deposited on the bottom electrode layers 132 to conform to the profiles of the bottom electrode layers 132. Thus, the insulator layers 134 are deposited on the sidewalls and on the bottom surfaces (which correspond to the top surfaces of the first bottom contact 128a and second bottom contact 128b) of the trenches 302. In some implementations, a deposition tool is used to conformally deposit the insulator layers 134 such that the insulator layers 134 conform to the profiles of the bottom electrode layers 132. In some implementations, a conformal CVD technique and/or an ALD technique is used to deposit the insulator layers 134.

As shown in FIG. 3F, the sacrificial layers 304 are removed from between the remaining portions of the first and second additional insulator layers 146 and 148 to form the air gaps 144 between the first and second additional insulator layers 146 and 148. The removal may be performed by using an etch tool to selectively etch the sacrificial layer 304 with respect to the ESL 116c, the insulator layer 134, and the first and second additional insulator layers 146 and 148. In some implementations, the selective etching operation is performed using a fluorine-based etchant which selectively etches a material of the sacrificial layer 304 approximately 500 times to approximately 1000 times faster than the materials of the ESL 116 c, the insulator layer 134, and the first and second additional insulator layers 146 and 148.

As shown in FIG. 3G, the top electrode layer 136 may be deposited on the insulator layers 134. The top electrode layer 136 may be deposited such that the top electrode layer 136 fills the remaining areas of the trenches 302 not occupied by the bottom electrode layers 132, insulator layers 134, air gaps 144, first additional insulator layers 146, and second additional insulator layers 148. The top electrode layer 136 may also be deposited on the top surface of the ESL 116c between adjacent trenches 302. Deposition of the top electrode layer 136 does not penetrate beyond a top portion of an area between the first and second additional insulator layers 146 and 148, such that the top electrode layer 136 covers and/or encloses the air gaps 144 at top portions thereof. In some implementations, a deposition tool is used to conformally deposit the top electrode layer 136 using a PVD technique, a CVD technique, an ALD technique, and/or another suitable deposition technique. The material of the top electrode layer 136 may be deposited directionally, and may not fill the areas between the first and second additional insulator layers 146 and 148 beyond a certain depth due to limitations in the step coverage and/or aspect ratio of the deposition process. Additionally, surface tension and other forces may prevent the material of the top electrode layer 136 from penetrating beyond a top portion into the spaces between the first and second additional insulator layers 146 and 148.

As shown in FIG. 3H, capping layers are formed above the trenches 302 of the trench capacitor structure 126a. For example, the oxide capping layer 138 may be formed above and/or on the top electrode layer 136, the oxynitride capping layer 140 may be formed above and/or on the oxide capping layer 138, and/or the nitride capping layer 142 may be formed above and/or on the oxynitride capping layer 140, among other examples.

A deposition tool may be used to deposit the oxide capping layer 138, the oxynitride capping layer 140, and/or the nitride capping layer 142 using a PVD technique, an ALD technique, a CVD technique, an oxidation technique, and/or another suitable deposition technique. The oxide capping layer 138, the oxynitride capping layer 140, and/or the nitride capping layer 142 may be deposited in one or more deposition operations. In some implementations, a planarization tool may be used to perform a planarization operation (e.g., a CMP operation) to planarize the oxide capping layer 138, the oxynitride capping layer 140, and/or the nitride capping layer 142 after the oxide capping layer 138, the oxynitride capping layer 140, and/or the nitride capping layer 142 is deposited.

As shown in FIG. 3I, additional material of the ILD layer 114c may be formed to encapsulate the trench capacitor structure 126a. A deposition tool may be used to deposit the additional material of the ILD layer 114c using a PVD technique, an ALD technique, a CVD technique, an epitaxy technique, an oxidation technique, and/or another suitable deposition technique. The additional material of the ILD layer 114c may be deposited in one or more deposition operations. In some implementations, a planarization tool may be used to perform a planarization operation (e.g., a CMP operation) to planarize the ILD layer 114c after the additional material of the ILD layer 114c is deposited.

As shown in FIG. 3J, a recess 306 may be formed in the ILD layer 114c, through the capping layers 138-142, and to the top electrode layer 136 of the trench capacitor structure 126a. Thus, the top electrode layer 136 may be exposed through the recess 306.

In some implementations, a pattern in a photoresist layer is used to etch the ILD layer 114c, the oxide capping layer 138, the oxynitride capping layer 140, and/or the nitride capping layer 142 to form the recess 306. In these implementations, a deposition tool may be used to form the photoresist layer on the ILD layer 114c. An exposure tool may be used to expose the photoresist layer to a radiation source to pattern the photoresist layer. A developer tool may be used to develop and remove portions of the photoresist layer to expose the pattern. An etch tool may be used to etch the ILD layer 114c, the oxide capping layer 138, the oxynitride capping layer 140, and/or the nitride capping layer 142 based on the pattern to form the recess 306. In some implementations, one or more etch operations are performed to etch the ILD layer 114c, the oxide capping layer 138, the oxynitride capping layer 140, and/or the nitride capping layer 142. In some implementations, the one or more etch operations may include a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 306 based on a pattern.

As shown in FIG. 3K, the top contact 130 may be formed in the recess 306. A deposition tool may be used to deposit the material of the top contact 130 using a CVD technique, a PVD technique, an ALD technique, an electroplating technique, and/or another suitable deposition technique. The top contact 130 may be deposited in one or more deposition operations. In some implementations, a seed layer is first deposited, and the top contact 130 is deposited on the seed layer. In some implementations, a planarization tool is used to perform a planarization operation (e.g., a CMP operation) to planarize the top contact 130 after the top contact 130 is deposited.

As indicated above, FIGS. 3A-3K are provided as an example. Other examples may differ from what is described with regard to FIGS. 3A-3K.

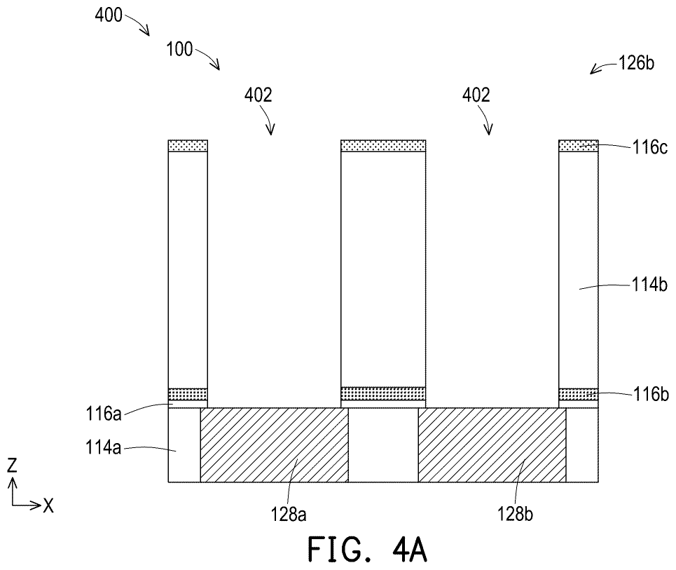

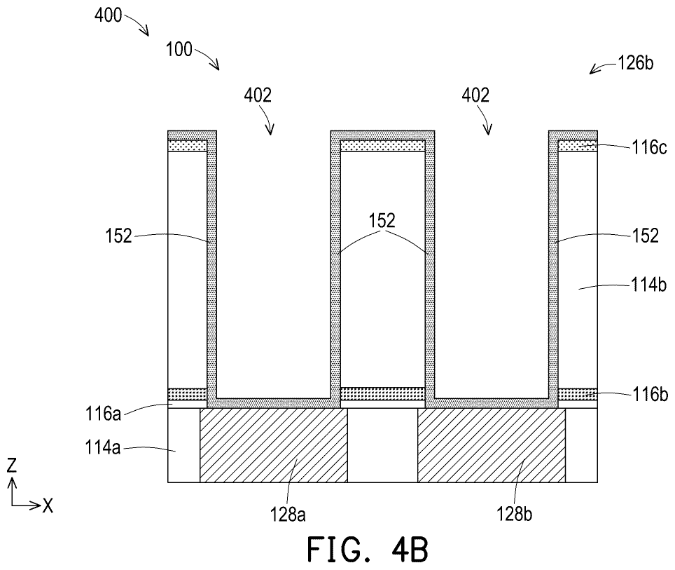

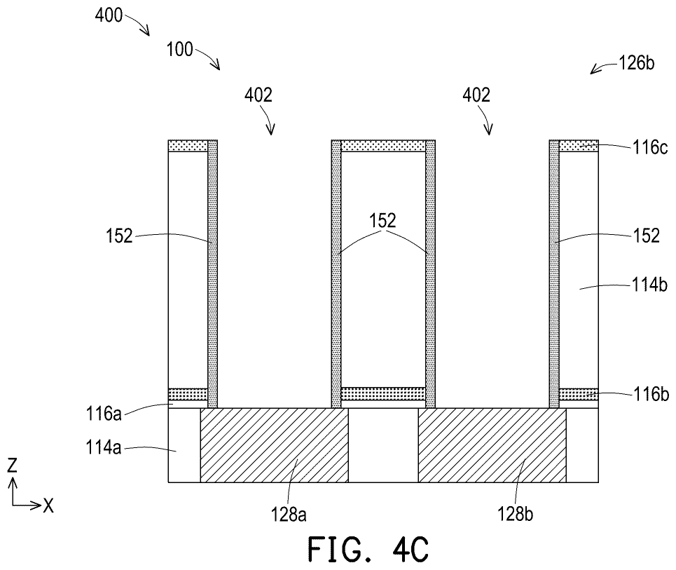

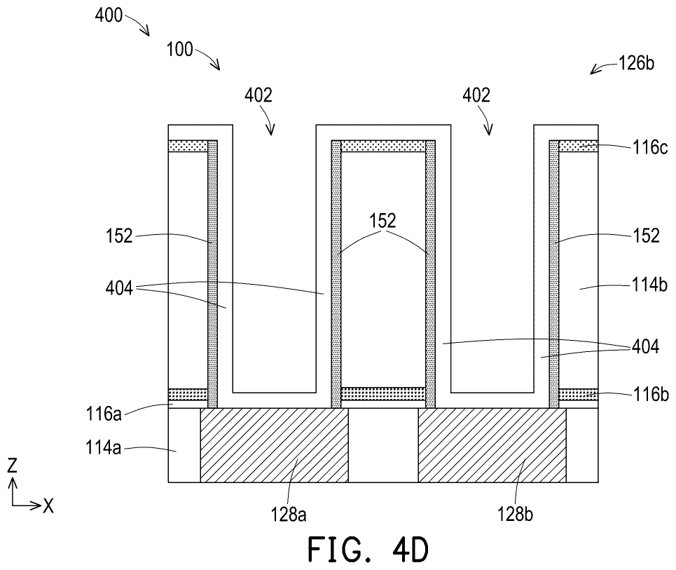

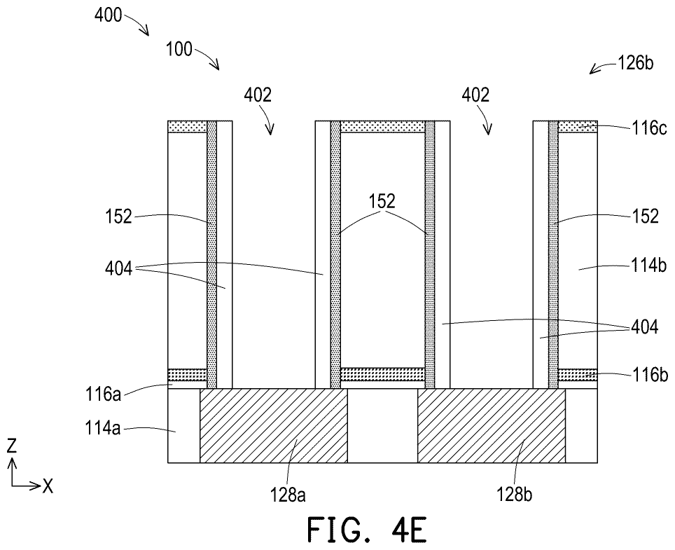

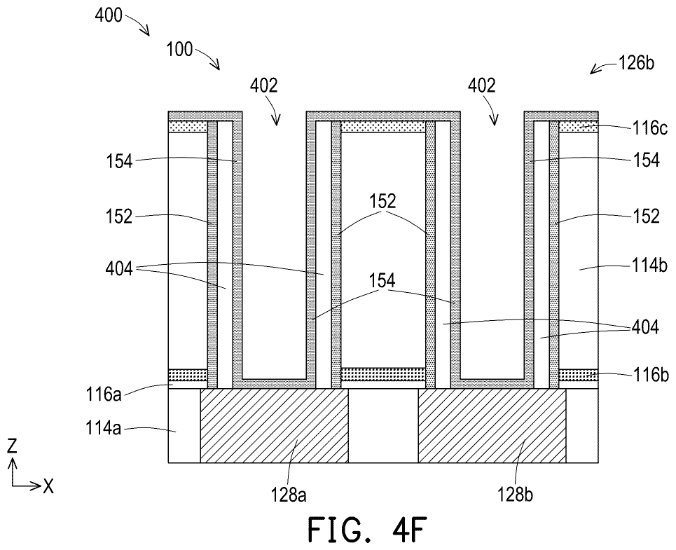

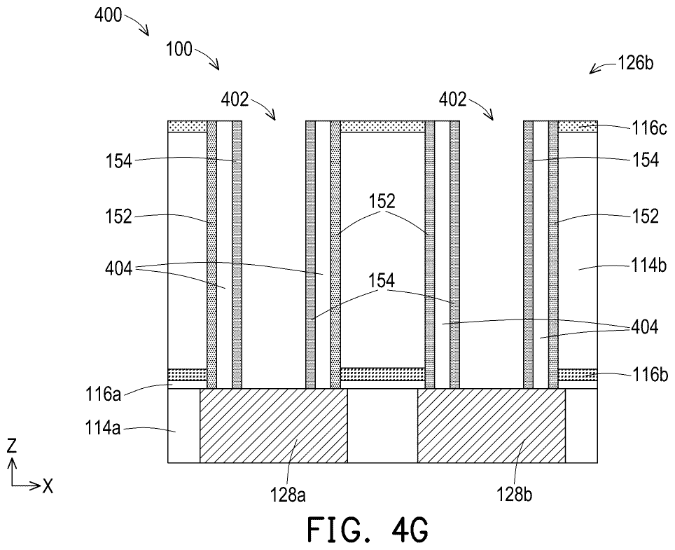

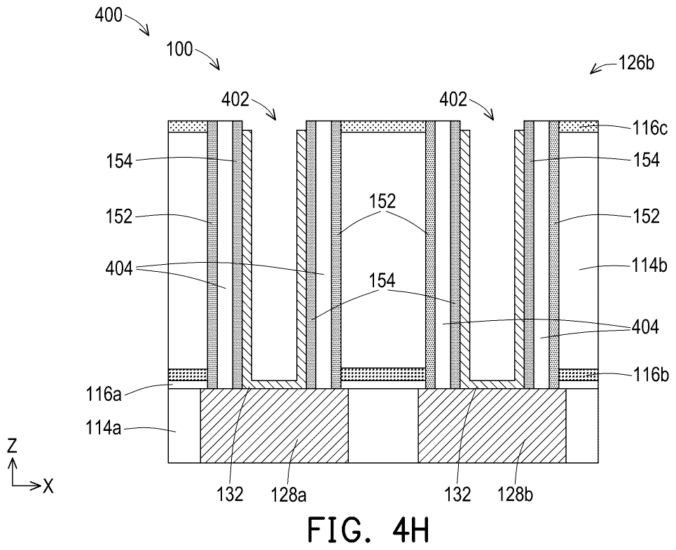

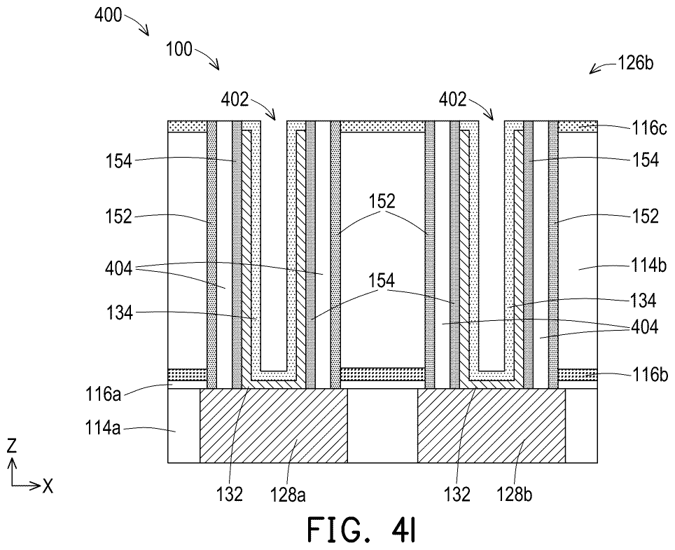

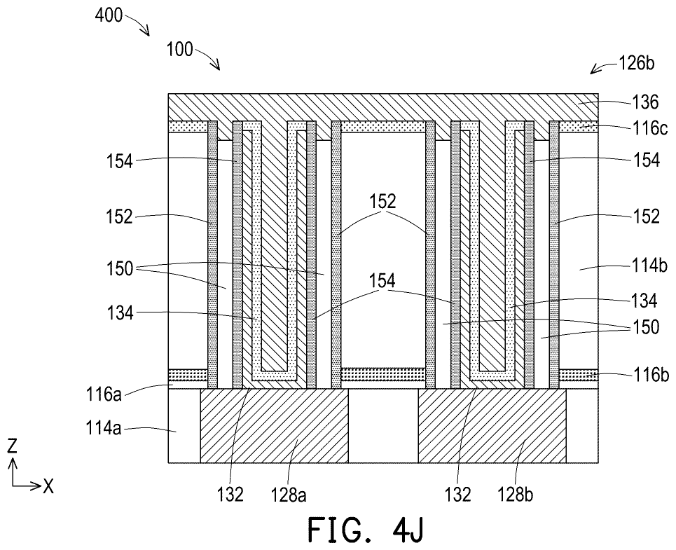

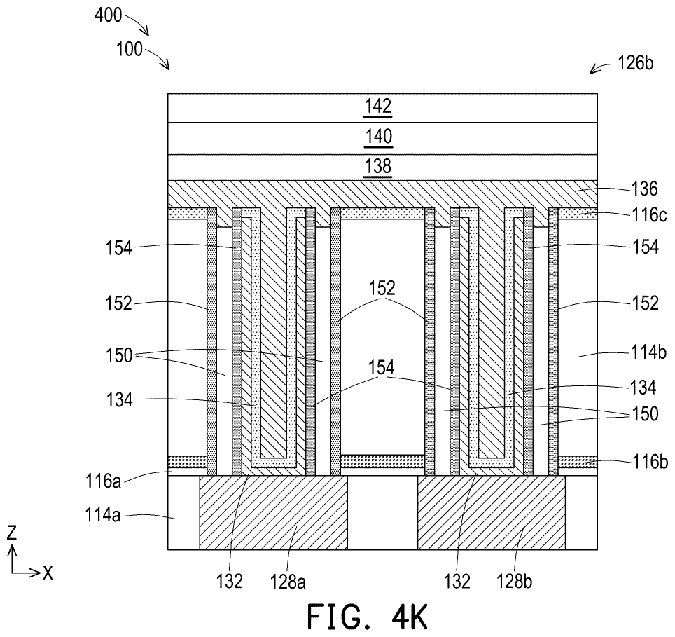

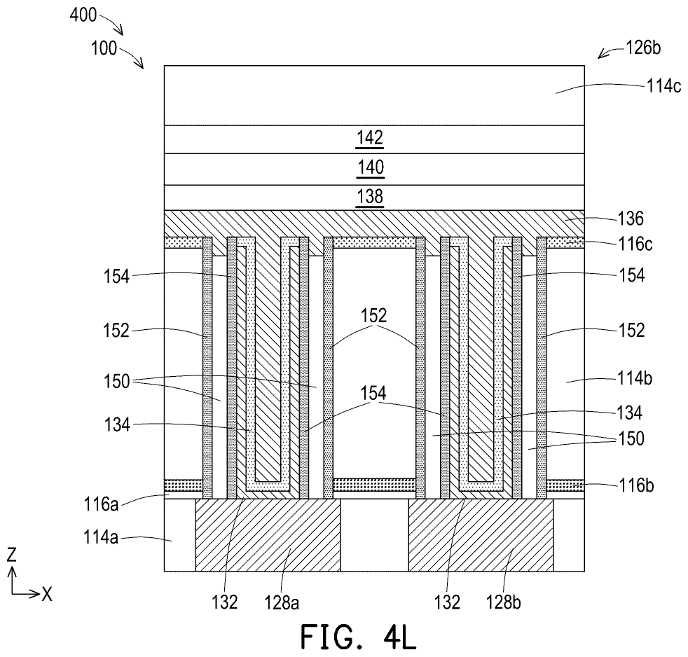

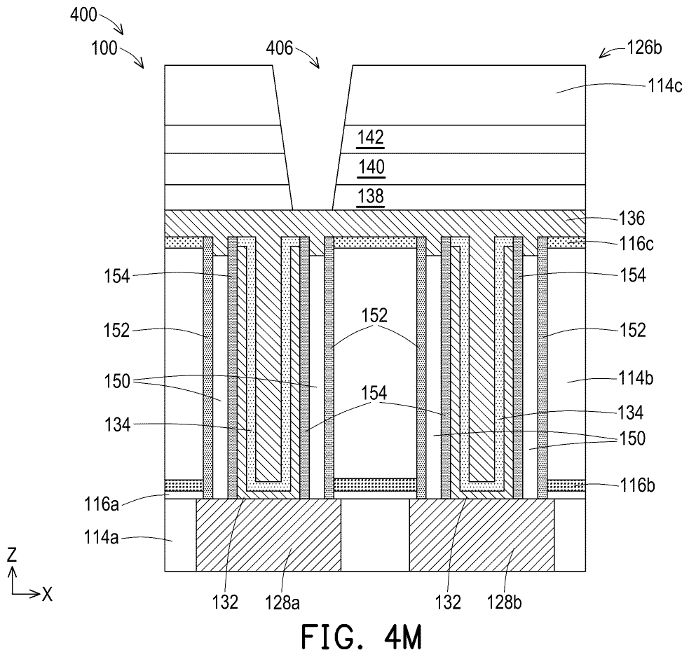

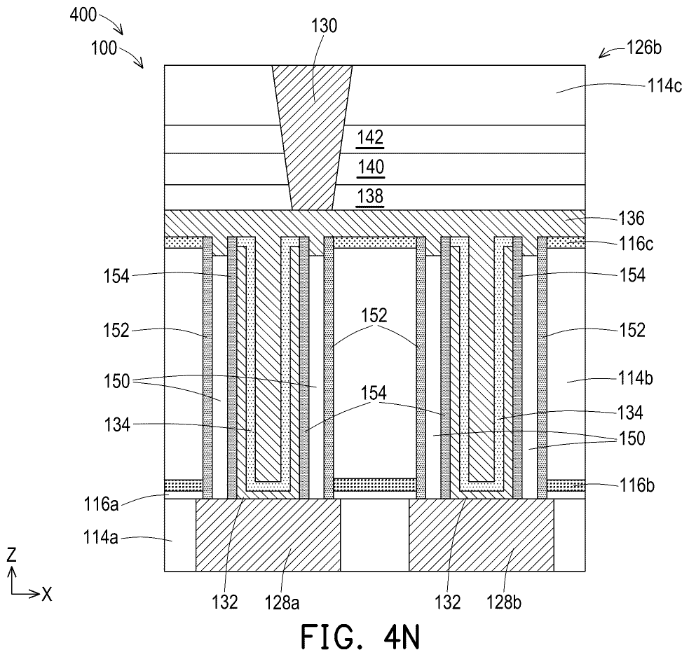

FIGS. 4A-4N are diagrams of an example implementation 400 of forming a trench capacitor structure 126b described herein. In some implementations, one or more of the semiconductor processing operations described in connection with FIGS. 4A-4N may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 4A-4N may be performed as part of the process for forming the semiconductor device 100 described in connection with FIGS. 2A-2E.

As shown in FIG. 4A, similar to what is described in connection with FIG. 3A, an etch operation, the same or similar to that performed in connection with the trench capacitor structure 126a, is performed to etch through the ILD layer 114b and through the ESLs 116a, 116b, and 116c to form the trenches 402 of the trench capacitor structure 126b. The etch operation may include a gas-based etch operation in which a gas-based etchant is used. An etch tool may be used to perform the gas-based etch operation.

As shown in FIG. 4B, the first additional insulator layer 152 may be deposited on the sidewalls and on the bottom surfaces of the trenches 402. The bottom surfaces of the trenches 402 correspond to the top surfaces of the first bottom contact 128a and second bottom contact 128b, and thus the first additional insulator layer 152 may be in physical contact with the top surfaces of the first bottom contact 128a and second bottom contact 128b. The first additional insulator layer 152 may also be deposited on the top surface of the ESL 116c between adjacent trenches 402 such that the first additional insulator layer 152 may be in physical contact with the top surface of the ESL 116c. In some implementations, a deposition tool is used to conformally deposit the first additional insulator layer 152 such that the first additional insulator layer 152 conforms to the profile of the trenches 402. In some implementations, a conformal CVD technique and/or an ALD technique is used to deposit the first additional insulator layer 152.

As shown in FIG. 4C, portions of the first additional insulator layer 152 are removed in an etching operation. In some implementations, a masking layer may be formed on the first additional insulator layer 152, and an etch tool may be used to etch the masking layer based on a pattern in a photoresist layer to transfer the pattern to the masking layer. The resulting patterned masking layer may cover portions of the first additional insulator layer 152 that are to remain, and expose portions of the first additional insulator layer 152 that are to be removed. In some implementations, the etch operation to remove the portions of the first additional insulator layer 152 based on the pattern in the masking layer includes a dry etch operation (e.g., a plasma-based etch operation, a gas-based etch operation) using oxygen gas, hydrogen gas, hydrocarbon-containing gases, and/or fluorine-containing gases.

As shown in FIG. 4D, a sacrificial layer 404 may be deposited on the sidewalls of the trenches 402. The sidewalls of the trenches 402 include the remaining portions of the first additional insulator layer 152 thereon. The sacrificial layer 404 is further deposited on the bottom surfaces of the trenches 402. The bottom surfaces of the trenches 402 correspond to the top surfaces of the first bottom contact 128a and second bottom contact 128b, and thus the sacrificial layer 404 may be in physical contact with the top surfaces of the first bottom contact 128a and second bottom contact 128b. The sacrificial layer 404 may also be deposited on the top surface of the ESL 116c between adjacent trenches 402 such that the sacrificial layer 404 may be in physical contact with the top surface of the ESL 116c. In some implementations, a deposition tool is used to conformally deposit the sacrificial layer 404 such that the sacrificial layer 404 conforms to the profile of the trenches 402. In some implementations, a conformal CVD technique and/or an ALD technique is used to deposit the sacrificial layer 404. The sacrificial layer 404 may include a silicon oxide (e.g., SiO₂), an oxynitride containing dielectric material such as silicon oxynitride (SiON), a silicon nitride (e.g., SiN), a silicon carbonitride (e.g., SiCN), and/or other low-k dielectric materials.

As shown in FIG. 4E, portions of the sacrificial layer 404 are removed in an etching operation. In some implementations, a masking layer may be formed on the sacrificial layer 404, and an etch tool may be used to etch the masking layer based on a pattern in a photoresist layer to transfer the pattern to the masking layer. The resulting patterned masking layer may cover portions of the sacrificial layer 404 that are to remain, and expose portions of the sacrificial layer 404 that are to be removed. In some implementations, the etch operation to remove the portions of the sacrificial layer 404 based on the pattern in the masking layer includes a dry etch operation (e.g., a plasma-based etch operation, a gas-based etch operation) using oxygen gas, hydrogen gas, hydrocarbon-containing gases, and/or fluorine-containing gases.

As shown in FIG. 4F, the second additional insulator layer 154 may be deposited on the sidewalls of the trenches 402. The sidewalls of the trenches 402 include the remaining portions of the sacrificial layer 404 thereon. The second additional insulator layer 154 is further deposited on the bottom surfaces of the trenches 402. The bottom surfaces of the trenches 402 correspond to the top surfaces of the first bottom contact 128a and second bottom contact 128b, and thus the second additional insulator layer 154 may be in physical contact with the top surfaces of the first bottom contact 128a and second bottom contact 128b. The second additional insulator layer 154 may also be deposited on the top surface of the ESL 116c between adjacent trenches 402 such that the second additional insulator layer 154 may be in physical contact with the top surface of the ESL 116c. The second additional insulator layer 154 is also deposited on top surfaces of the remaining portions of the first additional insulator layer 152, and on top surfaces of the remaining portions of the sacrificial layer 404. In some implementations, a deposition tool is used to conformally deposit the second additional insulator layer 154 such that the second additional insulator layer 154 conforms to the profile of the trenches 402. In some implementations, a conformal CVD technique and/or an ALD technique is used to deposit the sacrificial layer 404.

As shown in FIG. 4G, portions of the second additional insulator layer 154 are removed in an etching operation. In some implementations, a masking layer may be formed on the second additional insulator layer 154, and an etch tool may be used to etch the masking layer based on a pattern in a photoresist layer to transfer the pattern to the masking layer. The resulting patterned masking layer may cover portions of the second additional insulator layer 154 that are to remain, and expose portions of the second additional insulator layer 154 that are to be removed. In some implementations, the etch operation to remove the portions of the second additional insulator layer 154 based on the pattern in the masking layer includes a dry etch operation (e.g., a plasma-based etch operation, a gas-based etch operation) using oxygen gas, hydrogen gas, hydrocarbon-containing gases, and/or fluorine-containing gases.

As shown in FIG. 4H, the bottom electrode layers 132 may be deposited in the trenches 402 on exposed side surfaces of remaining portions of a stacked arrangement of the first additional insulator layer 152, the sacrificial layer 404, and the second additional insulator layer 154. The bottom electrode layers 132 are further deposited on the bottom surfaces (which correspond to the top surfaces of the first bottom contact 128a and second bottom contact 128b) of the trenches 402. The bottom surfaces of the trenches 402 correspond to the top surfaces of the first bottom contact 128a and second bottom contact 128b, and thus the bottom electrode layers 132 may be in physical contact with the top surfaces of the first bottom contact 128a and second bottom contact 128b. In some implementations, a deposition tool is used to conformally deposit the bottom electrode layers 132 in the trenches 402 such that the bottom electrode layers 132 conform to the profile of the trenches 402, including the exposed side surfaces of the remaining portions of the stacked arrangement of the first additional insulator layer 152, the sacrificial layer 404, and the second additional insulator layer 154, and the exposed top surfaces of the first bottom contact 128a and second bottom contact 128b. In some implementations, a conformal CVD technique and/or an ALD technique is used to deposit the bottom electrode layers 132.

As shown in FIG. 4I, the insulator layers 134 may be deposited on the bottom electrode layers 132 to conform to the profiles of the bottom electrode layers 132. Thus, the insulator layers 134 are deposited on the sidewalls and on the bottom surfaces (which correspond to the top surfaces of the first bottom contact 128a and second bottom contact 128b) of the trenches 402. In some implementations, a deposition tool is used to conformally deposit the insulator layers 134 such that the insulator layers 134 conform to the profiles of the bottom electrode layers 132. In some implementations, a conformal CVD technique and/or an ALD technique is used to deposit the insulator layers 134.

As shown in FIG. 4J, the sacrificial layers 404 are removed from between the remaining portions of the first and second additional insulator layers 152 and 154 to form the air gaps 150 between the first and second additional insulator layers 152 and 154. The removal may be performed by using an etch tool to selectively etch the sacrificial layer 404 with respect to the ESL 116c, the insulator layer 134, and the first and second additional insulator layers 152 and 154. In some implementations, the selective etching operation is performed using a fluorine-based etchant which selectively etches a material of the sacrificial layer 404 approximately 500 times to approximately 1000 times faster than the materials of the ESL 116c, the insulator layer 134, and the first and second additional insulator layers 146 and 148.

As further shown in FIG. 4J, the top electrode layer 136 may be deposited on the insulator layers 134. The top electrode layer 136 may be deposited such that the top electrode layer 136 fills the remaining areas of the trenches 402 not occupied by the bottom electrode layers 132, insulator layers 134, air gaps 150, first additional insulator layers 152, and second additional insulator layers 154. The top electrode layer 136 may also be deposited on the top surface of the ESL 116c between adjacent trenches 402. Deposition of the top electrode layer 136 does not penetrate beyond a top portion of an area between the first and second additional insulator layers 152 and 154, such that the top electrode layer 136 covers and/or encloses the air gaps 150 at top portions thereof. In some implementations, a deposition tool is used to conformally deposit the top electrode layer 136 using a PVD technique, a CVD technique, an ALD technique, and/or another suitable deposition technique. The material of the top electrode layer 136 may be deposited directionally, and may not fill the areas between the first and second additional insulator layers 152 and 154 beyond a certain depth due to limitations in the step coverage and/or aspect ratio of the deposition process. Additionally, surface tension and other forces may prevent the material of the top electrode layer 136 from penetrating beyond a top portion into the spaces between the first and second additional insulator layers 152 and 154.

The remaining operations for formation of the capping layers 138-142, for formation of the additional material of ILD layer 114c, and for formation of the top contact 130 in a recess 406 as shown in FIGS. 4K-4N for the example implementation 400 are the same as or similar to the operations for formation of the capping layers 138-142, for formation of the additional material of ILD layer 114c, and for formation of the top contact 130 in the recess 306 as shown and described in connection with FIGS. 3H-3K for the example implementation 300.

As indicated above, FIGS. 4A-4N are provided as an example. Other examples may differ from what is described with regard to FIGS. 4A-4N.

FIGS. 5A-5K are diagrams of an example implementation 500 of forming a trench capacitor structure 126c described herein. In some implementations, one or more of the semiconductor processing operations described in connection with FIGS. 5A-5K may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 5A-5K may be performed as part of the process for forming the semiconductor device 100 described in connection with FIGS. 2A-2E.

As shown in FIG. 5A, similar to what is described in connection with FIGS. 3A and 4A, an etch operation the same or similar to that performed in connection with the trench capacitor structures 126a and/or 126b, is performed to etch through the ILD layer 114b and through the ESLs 116a, 116b, and 116c to form the trenches 502 of the trench capacitor structure 126c. The etch operation may include a gas-based etch operation in which a gas-based etchant is used. An etch tool may be used to perform the gas-based etch operation.

As shown in FIG. 5B, the sacrificial layer 158 may be deposited on the sidewalls and on the bottom surfaces of the trenches 502. The bottom surfaces of the trenches 502 correspond to the top surfaces of the first bottom contact 128a and second bottom contact 128b, and thus the sacrificial layer 158 may be in physical contact with the top surfaces of the first bottom contact 128a and second bottom contact 128b. The sacrificial layer 158 may also be deposited on the top surface of the ESL 116c between adjacent trenches 502 such that the sacrificial layer 158 may be in physical contact with the top surface of the ESL 116c. In some implementations, a deposition tool is used to conformally deposit the sacrificial layer 158 such that the sacrificial layer 158 conforms to the profile of the trenches 502. In some implementations, a conformal CVD technique and/or an ALD technique is used to deposit the sacrificial layer 158. The sacrificial layer 158 may include an aluminum oxynitride (e.g., AlON), an aluminum nitride (e.g., AlN), an aluminum oxide (e.g., AlO), a hafnium oxide (e.g., HfO), a zirconium oxide (e.g., ZrO), an indium zirconium oxide (e.g., InZrO), a hafnium zirconium oxide (e.g., HfZrO), a titanium oxide (e.g., TiO), a titanium aluminum oxide (e.g. TiAlO), a tantalum oxide (e.g., Ta₂O₅), and/or other materials.

As further shown in FIG. 5B, the additional insulator layer 160 may be deposited on the sacrificial layer 158. Thus, the additional insulator layer 160 is deposited on the sidewalls and on the bottom surfaces (which correspond to the top surface of the first bottom contact 128a and second bottom contact 128b) of the trenches 502. The additional insulator layer 160 may also be deposited on the top surface of the ESL 116c between adjacent trenches 502. In some implementations, a deposition tool is used to conformally deposit the additional insulator layer 160 such that the additional insulator layer 160 conforms to the profile of the trenches 502. In some implementations, a conformal CVD technique and/or an ALD technique is used to deposit the additional insulator layer 160.

As shown in FIG. 5C, portions of the stacked arrangement of the sacrificial layer 158 and the additional insulator layer 160 are removed in an etching operation. In some implementations, a masking layer may be formed on the additional insulator layer 160, and an etch tool may be used to etch the masking layer based on a pattern in a photoresist layer to transfer the pattern to the masking layer. The resulting patterned masking layer may cover portions of the stacked arrangement of the sacrificial layer 158 and the additional insulator layer 160 that are to remain, and expose portions of the stacked arrangement of the sacrificial layer 158 and the additional insulator layer 160 that are to be removed. In some implementations, the etch operation to remove the portions of the stacked arrangement of the sacrificial layer 158 and the additional insulator layer 160 based on the pattern in the masking layer includes a dry etch operation (e.g., a plasma-based etch operation, a gas-based etch operation) using oxygen gas, hydrogen gas, hydrocarbon-containing gases, and/or fluorine-containing gases.

As shown in FIG. 5D, the bottom electrode layers 132 may be deposited in the trenches 502 on exposed side surfaces of the remaining portions of the stacked arrangement of the sacrificial layer 158 and the additional insulator layer 160. The bottom electrode layers 132 are further deposited on the bottom surfaces (which correspond to the top surfaces of the first bottom contact 128a and second bottom contact 128b) of the trenches 502. The bottom surfaces of the trenches 502 correspond to the top surfaces of the first bottom contact 128a and second bottom contact 128b, and thus the bottom electrode layers 132 may be in physical contact with the top surfaces of the first bottom contact 128a and second bottom contact 128b. In some implementations, a deposition tool is used to conformally deposit the bottom electrode layers 132 in the trenches 502 such that the bottom electrode layers 132 conform to the profile of the trenches 502, including the exposed side surfaces of the remaining portions of the stacked arrangement of the sacrificial layer 158 and the additional insulator layer 160, and the exposed top surfaces of the first bottom contact 128a and second bottom contact 128b. In some implementations, a conformal CVD technique and/or an ALD technique is used to deposit the bottom electrode layers 132.

As shown in FIG. 5E, the insulator layers 134 may be deposited on the bottom electrode layers 132 to conform to the profiles of the bottom electrode layers 132. Thus, the insulator layers 134 are deposited on the sidewalls and on the bottom surfaces (which correspond to the top surfaces of the first bottom contact 128a and second bottom contact 128b) of the trenches 502. In some implementations, a deposition tool is used to conformally deposit the insulator layers 134 such that the insulator layers 134 conform to the profiles of the bottom electrode layers 132. In some implementations, a conformal CVD technique and/or an ALD technique is used to deposit the insulator layers 134.

As shown in FIG. 5F, portions of the sacrificial layers 158 are removed from between the ESL 116c and ILD layer 114b and remaining portions of the additional insulator layers 160 to form the air gaps 156 between the ESL 116c and ILD layer 114b and the additional insulator layers 160. The removal may be performed by using an etch tool to selectively etch each sacrificial layer 158 with respect to the ILD layer 114b, the ESL 116c, the insulator layers 134, and the additional insulator layers 160. In some implementations, the selective etching operation is performed using a mixture of a surfactant (e.g., polyethylene glycol ether, polyether ester, a sulfonate), a solvent (e.g., water, an acid, an alkaline material, ethylene glycol, propylene glycol methyl ether (PGME)), a chelating agent (e.g., ethylenediaminetetraacetic acid (EDTA), citric acid, glycolic acid), an inhibitor (e.g., benzotriazole (BTA), adipic acid dihydrazide (ADH), a phosphate), and a pH adjuster (e.g., sodium hydroxide, ammonium hydroxide, sulfuric acid, acetic acid), which selectively etches a material of the sacrificial layers 158 approximately 100 times to approximately 600 times faster than the materials of the ILD layer 114b, the ESL 116c, the insulator layers 134, and the additional insulator layers 160.

As shown in FIG. 5G, the top electrode layer 136 may be deposited on the insulator layers 134. The top electrode layer 136 may be deposited such that the top electrode layer 136 fills the remaining areas of the trenches 502 not occupied by the bottom electrode layers 132, insulator layers 134, air gaps 156, sacrificial layers 158, and the additional insulator layers 160. The top electrode layer 136 may also be deposited on the top surface of the ESL 116c between adjacent trenches 502. Deposition of the top electrode layer 136 does not penetrate beyond a top portion of an area between the ILD layer 114b and the additional insulator layers 160, such that the top electrode layer 136 covers and/or encloses the air gaps 156 at top portions thereof. In some implementations, a deposition tool is used to conformally deposit the top electrode layer 136 using a PVD technique, a CVD technique, an ALD technique, and/or another suitable deposition technique. The material of the top electrode layer 136 may be deposited directionally, and may not fill the areas between the ILD layer 114b and the additional insulator layers 160 beyond a certain depth due to limitations in the step coverage and/or aspect ratio of the deposition process. Additionally, surface tension and other forces may prevent the material of the top electrode layer 136 from penetrating beyond a top portion into the spaces between the ILD layer 114b and the additional insulator layers 160.

The remaining operations for formation of the capping layers 138-142, the formation of the additional material of ILD layer 114c, and for the formation of the top contact 130 in a recess 504 as shown in FIGS. 5H-5K for the example implementation 500 are the same as or similar to the operations for formation of the capping layers 138-142, the formation of the additional material of ILD layer 114c, and for the formation of the top contact 130 in the recess 306 as shown and described in connection with FIGS. 3H-3K for the example implementation 300.

As indicated above, FIGS. 5A-5K are provided as an example. Other examples may differ from what is described with regard to FIGS. 5A-5K.

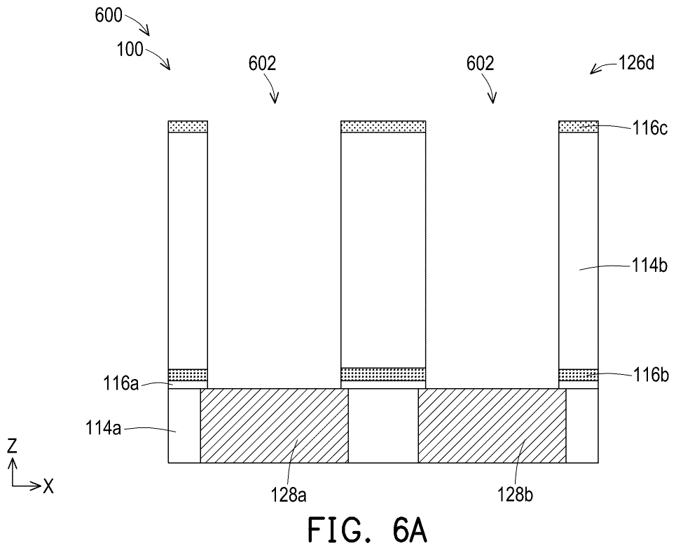

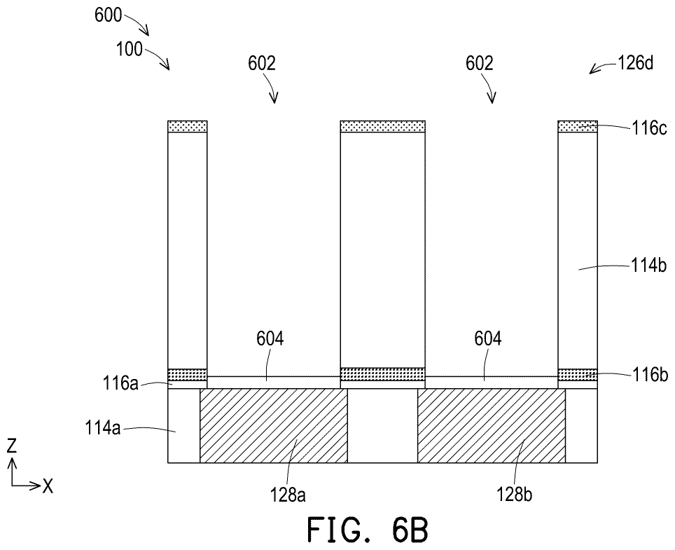

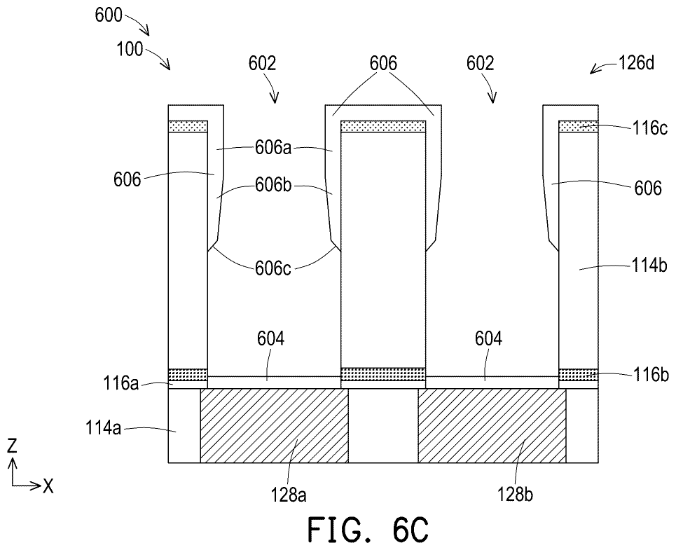

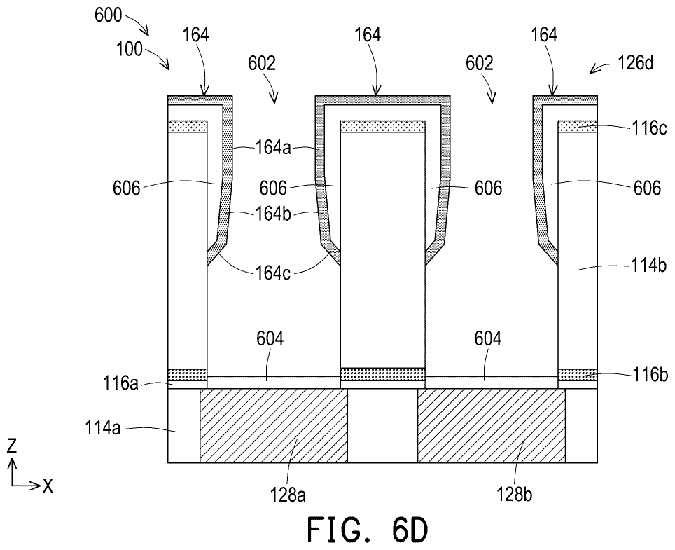

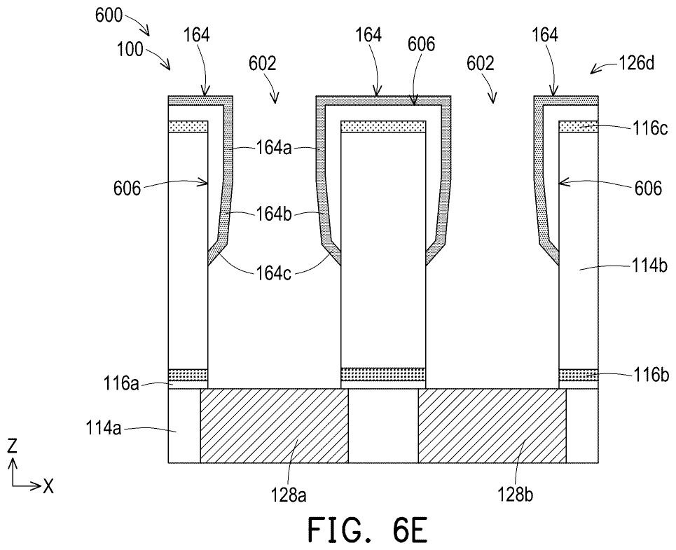

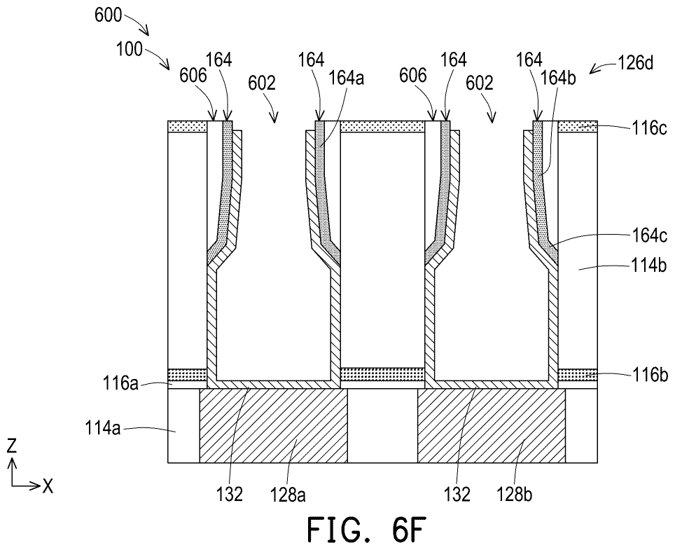

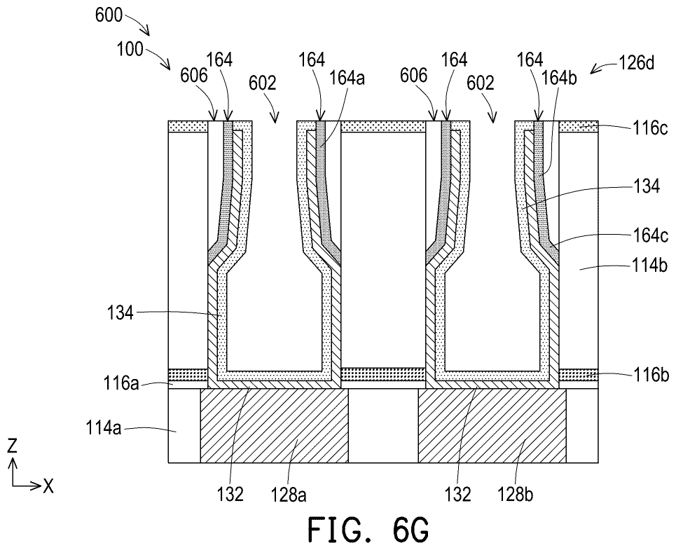

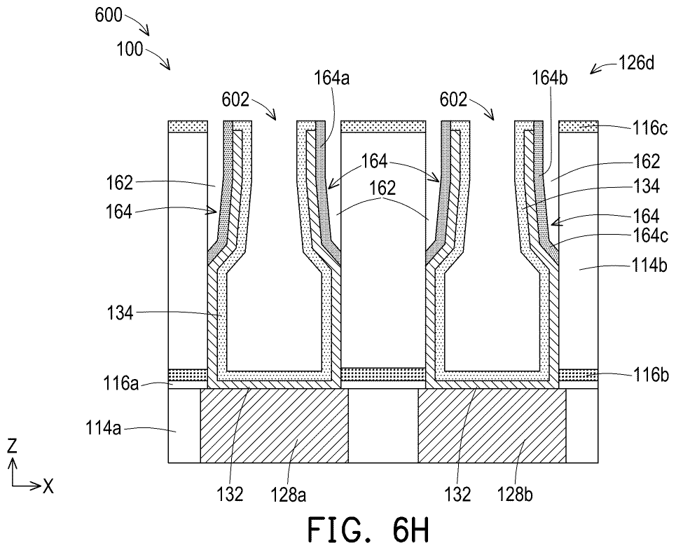

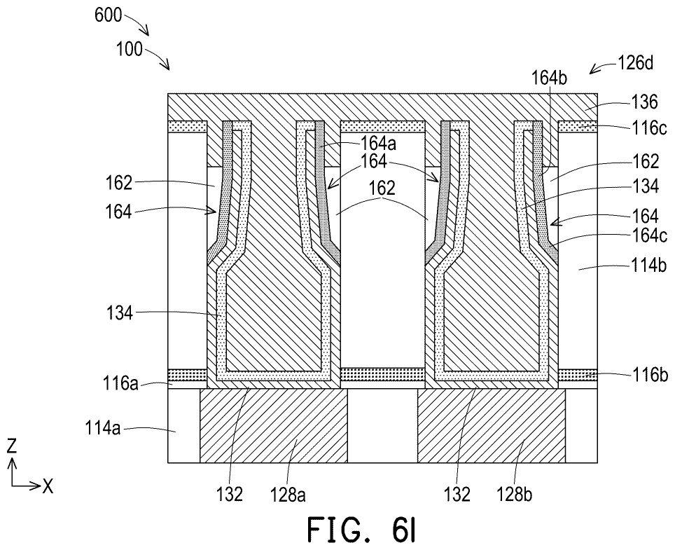

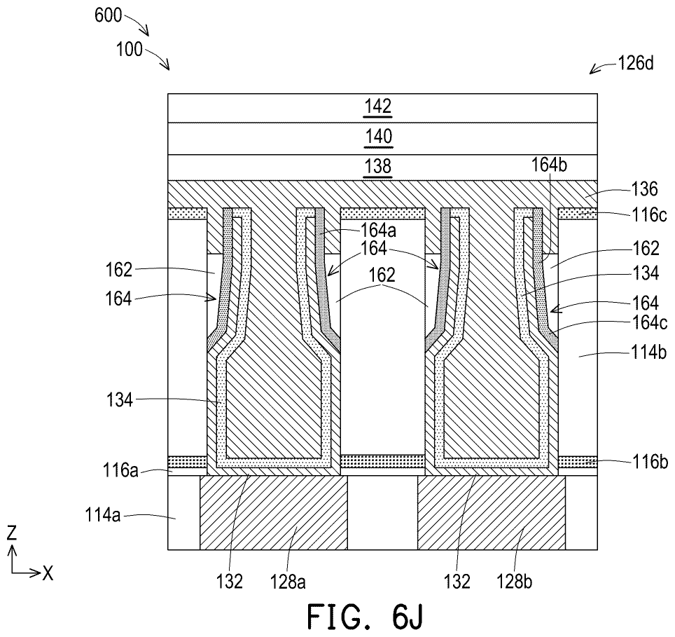

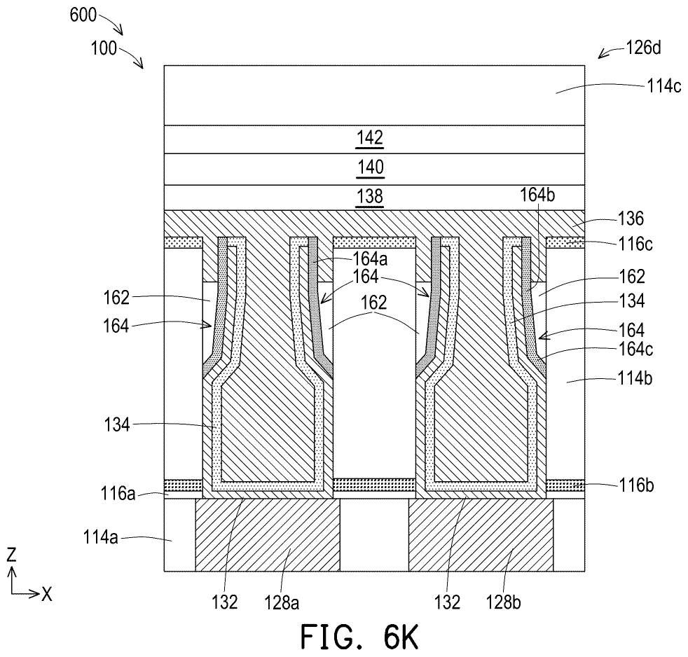

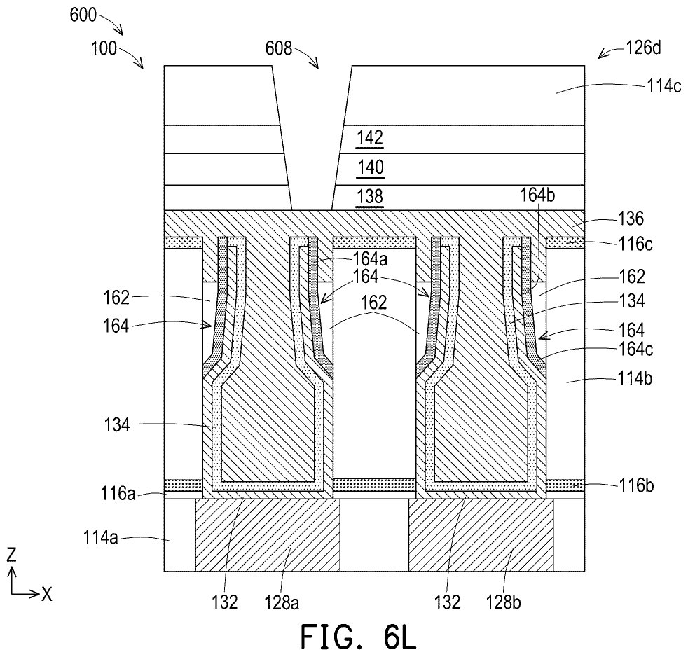

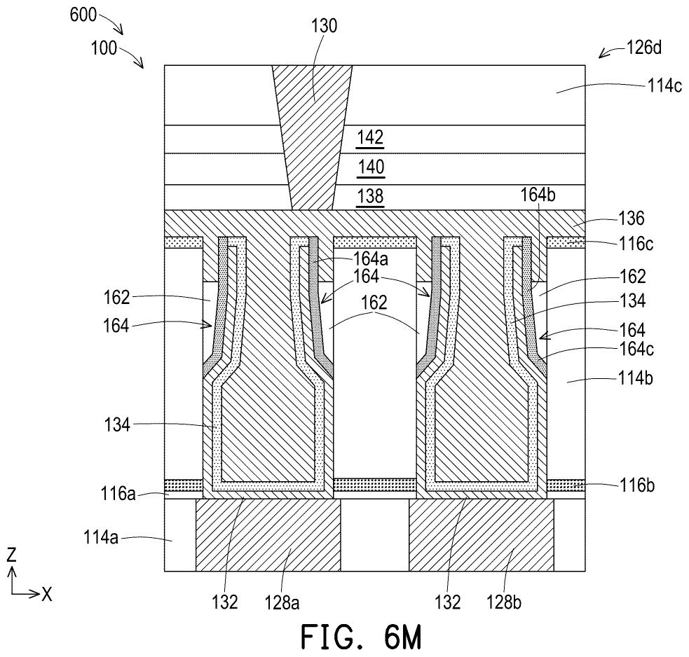

FIGS. 6A-6M are diagrams of an example implementation 600 of forming a trench capacitor structure 126d described herein. In some implementations, one or more of the semiconductor processing operations described in connection with FIGS. 6A-6M may be performed using one or more semiconductor processing tools, such as a deposition tool, an exposure tool, a developer tool, an etch tool, a planarization tool, a wafer/die transport tool, and/or another type of semiconductor processing tool. In some implementations, one or more of the semiconductor processing operations described in connection with FIGS. 6A-6M may be performed as part of the process for forming the semiconductor device 100 described in connection with FIGS. 2A-2E.

As shown in FIG. 6A, similar to what is described in connection with FIGS. 3A, 4A and 5A, an etch operation the same or similar to that performed in connection with the trench capacitor structures 126a, 126b and/or 126c, is performed to etch through the ILD layer 114b and through the ESLs 116a, 116b, and 116c to form the trenches 602 of the trench capacitor structure 126d. The etch operation may include a gas-based etch operation in which a gas-based etchant is used. An etch tool may be used to perform the gas-based etch operation.

As shown in FIG. 6B, a self-assembled monolayer (SAM) 604 is deposited in each of the trenches 602 on an exposed top surface of the first bottom contact 128a or an exposed top surface of the second bottom contact 128b. The SAMs 604 form chemical barriers on the first bottom contact 128a and the second bottom contact 128b to prevent subsequent material deposition onto the first bottom contact 128a and the second bottom contact 128b. The technique in which the SAMs are used may be referred to as selective deposition. In some implementations, a SAM 604 may include a thiol group compound, a silane, a phosphonate, a carboxylic acid, a disulfide, or a dithiocarbamate.

As shown in FIG. 6C, sacrificial layers 606 may be deposited on the ESL 116c between adjacent trenches 602 such that the sacrificial layers 606 may be in physical contact with the top surface of the ESL 116c. The sacrificial layers are also deposited on upper portions of the sidewalls of the trenches 602. The SAMs 604 prevent the deposition of the sacrificial layers 606 on the bottom surfaces of the trenches 602 corresponding to the top surfaces of the first bottom contact 128a and second bottom contact 128b. Directional deposition and/or fast sputtering of the sacrificial layers 606 toward the upper portions of the sidewalls of the trenches 602 may prevent the deposition of the sacrificial layers 606 on lower portions of the sidewalls of the trenches 602. For example, fast sputtering concentrates sputtered atoms to the upper portions of the sidewalls of the trenches 602 to target deposition to the upper portions of the sidewalls of the trenches 602 without forming the sacrificial layers 606 on other portions of the trenches 602. In some implementations, the sacrificial layers 606 may include an aluminum oxynitride (e.g., AlON), an aluminum nitride (e.g., AlN), an aluminum oxide (e.g., AlO), a hafnium oxide (e.g., HfO), a zirconium oxide (e.g., ZrO), an indium zirconium oxide (e.g., InZrO), a hafnium zirconium oxide (e.g., HfZrO), a titanium oxide (e.g., TiO), a titanium aluminum oxide (e.g. TiAlO), a tantalum oxide (e.g., Ta₂O₅), and/or other materials. The sacrificial layers 606 may have a curved and/or angular profile, with different segments 606a, 606b, 606c at different angles with respect to each other.

As shown in FIG. 6D, the additional insulator layers 164 may be conformally deposited on the sacrificial layers 606. Thus, the additional insulator layers 164 are deposited on the ESL 116c between adjacent trenches 602 and on the upper portions of the sidewalls of the trenches 602. The additional insulator layers 164 conform to the profiles of the sacrificial layers 606 on which they are formed. More specifically, the additional insulator layers 164 each have a curved and/or angular profile, with different segments 164a, 164b, 164c at different angles with respect to each other. The segments 164a-164c of the additional insulator layers 164 conform to the profiles of the segments 606a-606c of the sacrificial layers 606. In some implementations, a deposition tool is used to conformally deposit the additional insulator layers 164 such that the additional insulator layers 164 conform to the profiles of the sacrificial layers 606. In some implementations, a conformal CVD technique and/or an ALD technique is used to deposit the additional insulator layers 164.

As shown in FIG. 6E, the SAMs 604 are removed from the top surfaces of the first and second bottom contacts 128a and 128b in the trenches 602. In some implementations, the SAMs 604 may be removed by a baking process, where the semiconductor device 100 is heated to a temperature included in the range of approximately 100 degrees Celsius to approximately 150 degrees Celsius. However, other temperature ranges are included within the scope of this disclosure. Alternatively, the SAMs 604 may be removed by application of plasmas of hydrogen and/or oxygen to the SAMs 604.

As shown in FIG. 6F, the bottom electrode layers 132 may be deposited in the trenches 602 on exposed side surfaces of the additional insulator layers 164, and on exposed sidewalls of the ILD layer 114b and ESLs 116a and 116b in the trenches 602. The bottom electrode layers 132 are further deposited on the bottom surfaces (which correspond to the top surfaces of the first bottom contact 128a and second bottom contact 128b) of the trenches 602. The bottom surfaces of the trenches 602 correspond to the top surfaces of the first bottom contact 128a and second bottom contact 128b, and thus the bottom electrode layers 132 may be in physical contact with the top surfaces of the first bottom contact 128a and second bottom contact 128b. In some implementations, a deposition tool is used to conformally deposit the bottom electrode layers 132 in the trenches 602 such that the bottom electrode layers 132 conform to the profiles of the additional insulator layers 164, and to the sidewalls and bottom surfaces of the trenches 602. In some implementations, a conformal CVD technique and/or an ALD technique is used to deposit the bottom electrode layers 132.

As shown in FIG. 6G, the insulator layers 134 may be deposited on the bottom electrode layers 132 to conform to the profiles of the bottom electrode layers 132. Thus, the insulator layers 134 are deposited on the additional insulator layers 164, and on the sidewalls and the bottom surfaces (which correspond to the top surfaces of the first bottom contact 128a and second bottom contact 128b) of the trenches 602. In some implementations, a deposition tool is used to conformally deposit the insulator layers 134 such that the insulator layers 134 conform to the profiles of the bottom electrode layers 132. In some implementations, a conformal CVD technique and/or an ALD technique is used to deposit the insulator layers 134.

As shown in FIG. 6H, the sacrificial layers 606 are removed from between the ESL 116c and ILD layer 114b and the additional insulator layers 164 to form the air gaps 162 between the ESL 116c and ILD layer 114b and the additional insulator layers 164. The removal may be performed by using an etch tool to selectively etch each sacrificial layer 606 with respect to the ILD layer 114b, the ESL 116c, the insulator layers 134, and the additional insulator layers 164. In some implementations, the selective etching operation is performed using a mixture of a surfactant (e.g., polyethylene glycol ether, polyether ester, a sulfonate), a solvent (e.g., water, an acid, an alkaline material, ethylene glycol, propylene glycol methyl ether (PGME)), a chelating agent (e.g., ethylenediaminetetraacetic acid (EDTA), citric acid, glycolic acid), an inhibitor (e.g., benzotriazole (BTA), adipic acid dihydrazide (ADH), a phosphate), and a pH adjuster (e.g., sodium hydroxide, ammonium hydroxide, sulfuric acid, acetic acid), which selectively etches a material of the sacrificial layers 606 approximately 100 times to approximately 600 times faster than the materials of the ILD layer 114b, the ESL 116c, the insulator layers 134, and the additional insulator layers 164.

As shown in FIG. 6I, the top electrode layer 136 may be deposited on the insulator layers 134. The top electrode layer 136 may be deposited such that the top electrode layer 136 fills the remaining areas of the trenches 602 not occupied by the bottom electrode layers 132, insulator layers 134, air gaps 162, and the additional insulator layers 164. The top electrode layer 136 may also be deposited on the top surface of the ESL 116c between adjacent trenches 602. Deposition of the top electrode layer 136 does not penetrate beyond a top portion of an area between the ILD layer 114b and the additional insulator layers 164, such that the top electrode layer 136 covers and/or encloses the air gaps 162 at top portions thereof. In some implementations, a deposition tool is used to conformally deposit the top electrode layer 136 using a PVD technique, a CVD technique, an ALD technique, and/or another suitable deposition technique. The material of the top electrode layer 136 may be deposited directionally, and may not fill the areas between the ILD layer 114b and the additional insulator layers 164 beyond a certain depth due to limitations in the step coverage and/or aspect ratio of the deposition process. Additionally, surface tension and other forces may prevent the material of the top electrode layer 136 from penetrating beyond a top portion into the spaces between the ILD layer 114b and the additional insulator layers 164.

The remaining operations for formation of the capping layers 138-142, the formation of the additional material of ILD layer 114c, and for the formation of the top contact 130 in a recess 608 as shown in FIGS. 6J-6M for the example implementation 600 are the same as or similar to the operations for formation of the capping layers 138-142, the formation of the additional material of ILD layer 114c, and for the formation of the top contact 130 in the recess 306 as shown and described in connection with FIGS. 3H-3K for the example implementation 300.

As indicated above, FIGS. 6A-6M are provided as an example. Other examples may differ from what is described with regard to FIGS. 6A-6M.

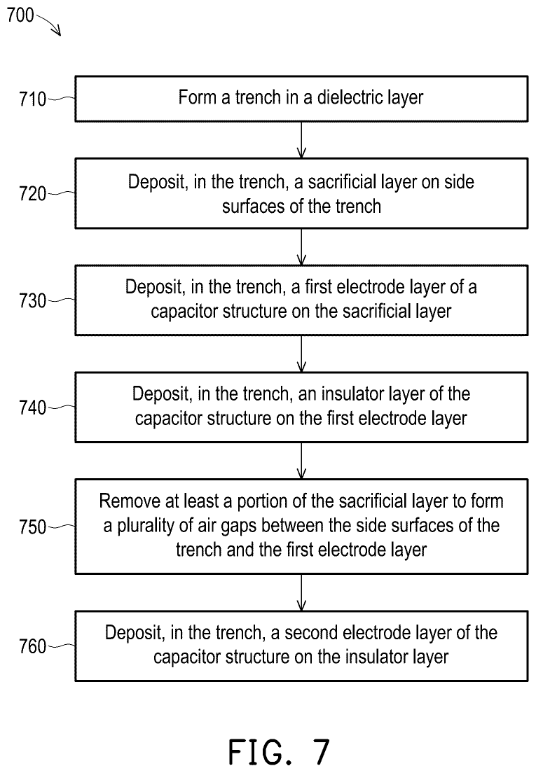

FIG. 7 is a flowchart of an example process 700 associated with a method of forming a semiconductor device. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a trench in a dielectric layer (block 710). For example, one or more semiconductor processing tools may be used to form a trench (e.g., trench 302, 402, 502, 602) in a dielectric layer (e.g., ILD layer 114b, ESLs 116a-c), as described herein.

As further shown in FIG. 7, process 700 may include depositing, in the trench, a sacrificial layer on side surfaces of the trench (block 720). For example, one or more semiconductor processing tools may be used to deposit, in the trench, a sacrificial layer (e.g., sacrificial layer 304, 404, 158, 606) on side surfaces of the trench, as described herein.

As further shown in FIG. 7, process 700 may include depositing, in the trench, a first electrode layer of a capacitor structure on the sacrificial layer (block 730). For example, one or more semiconductor processing tools may be used to deposit, in the trench, a first electrode layer (e.g., bottom electrode layer 132) of a capacitor structure (e.g., trench capacitor structure 126a, 126b, 126c, 126d) on the sacrificial layer, as described herein.

As further shown in FIG. 7, process 700 may include depositing, in the trench, an insulator layer of the capacitor structure on the first electrode layer (block 740). For example, one or more semiconductor processing tools may be used to deposit, in the trench, an insulator layer (e.g., insulator layer 134) of the capacitor structure on the first electrode layer, as described herein.

As further shown in FIG. 7, process 700 may include removing at least a portion of the sacrificial layer to form a plurality of air gaps between the side surfaces of the trench and the first electrode layer (block 750). For example, one or more semiconductor processing tools may be used to remove at least a portion of the sacrificial layer to form a plurality of air gaps (e.g., air gaps 144, 150, 156, 162) between the side surfaces of the trench and the first electrode layer, as described herein.

As further shown in FIG. 7, process 700 may include depositing, in the trench, a second electrode layer of the capacitor structure on the insulator layer (block 760). For example, one or more semiconductor processing tools may be used to deposit, in the trench, a second electrode layer (e.g., top electrode layer 136) of the capacitor structure on the insulator layer, as described herein.

Process 700 may include additional implementations, such as any single implementation or any combination of implementations described below and/or in connection with one or more other processes described elsewhere herein.

In a first implementation, the second electrode layer fills in top portions of the plurality of air gaps.

In a second implementation, alone or in combination with the first implementation, process 700 includes depositing, prior to depositing the first electrode layer, an additional insulator layer (e.g., additional insulator layer 148, 154, 160, 164) on the sacrificial layer, where the additional insulator layer isolates the first electrode layer from the second electrode layer.

In a third implementation, alone or in combination with one or more of the first and second implementations, removing at least a portion of the sacrificial layer includes selectively etching at least the portion of the sacrificial layer with respect to the first electrode layer and the insulator layer.

In a fourth implementation, alone or in combination with one or more of the first through third implementations, process 700 includes depositing, prior to depositing the sacrificial layer, a self-assembled monolayer (e.g., SAM 604) on an exposed contact structure at a bottom of the trench.

In a fifth implementation, alone or in combination with one or more of the first through fourth implementations, the self-assembled monolayer includes one of a thiol group compound, a silane, a phosphonate, a carboxylic acid, a disulfide, or a dithiocarbamate.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, air gaps are formed in capacitor structures to reduce parasitic capacitance between closely spaced capacitors. The air gaps may be formed on lateral sides of a deep trench capacitor (DTC) structure to ensure capacitor-to-capacitor isolation and reduced parasitic capacitance. Air gaps may be formed by selective film deposition and/or by selective removal of sacrificial layers. The dielectric constant (or relative permittivity) of the air gaps is less than the dielectric constant of porous low-k or bulk dielectric materials that may be used in other capacitor structures. The lesser dielectric constant of the air gaps in comparison to that of the porous low-k or bulk dielectric materials reduces the capacitive coupling between adjacent capacitor structures, thus suppressing cross-talk and increasing signal integrity. Moreover, unlike porous low-k or bulk dielectric materials, air gaps are not subject to manufacturing process damage. As a result, using air gap structures in capacitor structures in place of porous low-k or bulk dielectric materials can reduce RC delay, maintain stable capacitance, improve signal integrity, ensure more robust mechanical strength, and lower current leakage, leading to increased device performance and reliability.

As described in greater detail above, some implementations described herein provide a semiconductor structure. The semiconductor structure includes a first electrode layer that extends along sidewalls and a bottom surface of a trench, where the trench is in a dielectric layer. The semiconductor structure includes a second electrode layer in the trench. The semiconductor structure includes an insulator layer between the first electrode layer and the second electrode layer, where the insulator layer extends along the sidewalls and the bottom surface of the trench, and where the trench includes an air gap disposed between the first electrode layer and the dielectric layer.

As described in greater detail above, some implementations described herein provide a method. The method includes forming a trench in a dielectric layer. The method includes depositing, in the trench, a sacrificial layer on side surfaces of the trench. The method includes depositing, in the trench, a first electrode layer of a capacitor structure on the sacrificial layer. The method includes depositing, in the trench, an insulator layer of the capacitor structure on the first electrode layer. The method includes removing at least a portion of the sacrificial layer to form a plurality of air gaps between the side surfaces of the trench and the first electrode layer. The method includes depositing, in the trench, a second electrode layer of the capacitor structure on the insulator layer.

As described in greater detail above, some implementations described herein provide a semiconductor device. The semiconductor device includes a plurality of dielectric layers that are arranged in a first direction. The semiconductor device includes a plurality of trenches in the plurality of dielectric layers, where the plurality of trenches are arranged side-by-side in a second direction approximately perpendicular to the first direction, and where each trench of the plurality of trenches includes a first electrode layer of a capacitor structure, an insulator layer of the capacitor structure on the first electrode layer, a second electrode layer of the capacitor structure on the insulator layer, and a plurality of air gaps around the capacitor structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first electrode layer that extends along sidewalls and a bottom surface of a trench,
wherein the trench is in a dielectric layer;
a second electrode layer in the trench; and
an insulator layer between the first electrode layer and the second electrode layer,
wherein the insulator layer extends along the sidewalls and the bottom surface of the trench, and
wherein the trench includes an air gap disposed between the first electrode layer and the dielectric layer.

2. The semiconductor structure of claim 1, wherein the air gap is located along the sidewalls of the trench.

3. The semiconductor structure of claim 1, further comprising additional insulator layers in the trench,
wherein the additional insulator layers are disposed on side portions of the first electrode layer, and
wherein the additional insulator layers are between the air gap and the side portions of the first electrode layer.

4. The semiconductor structure of claim 1, wherein portions of the second electrode layer are disposed over the air gap.

5. The semiconductor structure of claim 1, wherein the air gap extends from a top portion of the trench to a bottom portion of the trench.

6. The semiconductor structure of claim 1, wherein a depth of the air gap is smaller than a total depth of the trench.

7. The semiconductor structure of claim 1, further comprising additional insulator layers in the trench,
wherein the additional insulator layers are disposed under the air gap.

8. The semiconductor structure of claim 1, further comprising a plurality of additional insulator layers on opposite sides of the air gap in the trench.

9. The semiconductor structure of claim 8, wherein first additional insulator layers of the plurality of additional insulator layers are disposed on side surfaces of the dielectric layer, and
wherein second additional insulator layers of the plurality of additional insulator layers are on side surfaces of the first electrode layer.

10. The semiconductor structure of claim 1, wherein a width of the air gap is substantially uniform in a direction from a top of the trench to a bottom of the trench.

11. The semiconductor structure of claim 1, wherein a width of the air gap decreases in a direction from a top of the trench to a bottom of the trench.

12. A method, comprising:
forming a trench in a dielectric layer;
depositing, in the trench, a sacrificial layer on side surfaces of the trench;
depositing, in the trench, a first electrode layer of a capacitor structure on the sacrificial layer;
depositing, in the trench, an insulator layer of the capacitor structure on the first electrode layer;
removing at least a portion of the sacrificial layer to form a plurality of air gaps between the side surfaces of the trench and the first electrode layer; and
depositing, in the trench, a second electrode layer of the capacitor structure on the insulator layer.

13. The method of claim 12, wherein the second electrode layer fills in top portions of the plurality of air gaps.

14. The method of claim 13, further comprising depositing, prior to depositing the first electrode layer, an additional insulator layer on the sacrificial layer,
wherein the additional insulator layer isolates the first electrode layer from the second electrode layer.

15. The method of claim 12, wherein removing at least a portion of the sacrificial layer comprises selectively etching at least the portion of the sacrificial layer with respect to the first electrode layer and the insulator layer.

16. The method of claim 12, further comprising depositing, prior to depositing the sacrificial layer, a self-assembled monolayer on an exposed contact structure at a bottom of the trench.

17. The method of claim 16, wherein the self-assembled monolayer comprises one of a thiol group compound, a silane, a phosphonate, a carboxylic acid, a disulfide, or a dithiocarbamate.

18. A semiconductor device, comprising:
a plurality of dielectric layers that are arranged in a first direction;
a plurality of trenches in the plurality of dielectric layers,
wherein the plurality of trenches are arranged side-by-side in a second direction approximately perpendicular to the first direction, and
wherein each trench of the plurality of trenches comprises:
a first electrode layer of a capacitor structure;
an insulator layer of the capacitor structure on the first electrode layer;
a second electrode layer of the capacitor structure on the insulator layer; and
a plurality of air gaps around the capacitor structure.

19. The semiconductor device of claim 18, wherein the plurality of air gaps are enclosed by portions of the second electrode layer.

20. The semiconductor device of claim 19, wherein each trench of the plurality of trenches further comprises a plurality of additional insulator layers,
wherein the plurality of additional insulator layers are disposed between the plurality of air gaps and first portions of the first electrode layer, and
wherein the plurality of additional insulator layers are disposed between the portions of the second electrode layer and second portions of the first electrode layer.
